(19) United States
(12) Patent Application Publication
(10) Pub. No.: US 2024/0172466 A1
(43) Pub. Date: May 23, 2024

(54) DISPLAY APPARATUS

(71) Applicant: Samsung Display Co., Ltd., Yongin-si (KR)

(72) Inventors: Seunglyong Bok, Yongin-si (KR); Byounghun Sung, Yongin-si (KR)

(21) Appl. No.: 18/221,781

(22) Filed: Jul. 13, 2023

(30) Foreign Application Priority Data
Nov. 21, 2022 (KR) 10-2022-0156685

(51) Int. Cl. H10K 50/125; H10K 59/121; H10K 59/122; H10K 71/10

(52) U.S. Cl. CPC H10K 50/125; H10K 59/121; H10K 59/122; H10K 71/10; H10K 2102/301

(57) ABSTRACT

Provided is a display apparatus comprising a substrate including emission areas and a sensing area, organic light-emitting diodes corresponding to the emission areas, and a photo detector disposed on the substrate and overlapping the sensing area, wherein each organic light-emitting diode includes a pixel electrode, a lower emission layer disposed on the pixel electrode, an upper emission layer disposed on the lower emission layer, and an opposite electrode disposed on the upper emission layer, and the photo detector includes a pixel electrode, an active layer disposed on the pixel electrode, and an opposite electrode disposed on the active layer.

### CROSS-REFERENCE TO RELATED APPLICATION

This application is based on and claims priority under 35 U.S.C. § 119 to Korean Patent Application No. 10-2022-0156685, filed on Nov. 21, 2022, in the Korean Intellectual Property Office, the disclosure of which is incorporated by reference herein in its entirety.

### BACKGROUND

### 1. Field

One or more embodiments generally relate to a structure of a display apparatus. More particularly, one of more embodiments relate to a structure of a display apparatus capable of improving display quality by applying tandem elements and including an optical sensor with improved sensing force.

### 2. Description of the Related Art

In general, a display apparatus operates as a thin-film transistor and display elements, such as organic light-emitting diodes, are formed on a substrate and light is emitted from the display elements.

In detail, each pixel of a display apparatus includes a display element, e.g., an organic light-emitting diode, in which an intermediate layer including an emission layer is arranged between a pixel electrode and an opposite electrode. A display apparatus generally controls whether each pixel emits light or an emission degree of each pixel by using a thin-film transistor electrically connected to a pixel electrode. Some layers included in the intermediate layer of the display element are commonly included in the display elements.

### SUMMARY

One or more embodiments include a display apparatus having improved display quality by applying tandem elements and including an optical sensor with improved sensing force. However, this is merely an example, and the scope of the present disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate including a first emission area, a second emission area, a third emission area, and a sensing area, a first organic light-emitting diode disposed on the substrate, corresponding to the first emission area, and emitting a first light, a second organic light-emitting diode disposed on the substrate, corresponding to the second emission area, and emitting a second light, a third organic light-emitting diode disposed on the substrate, overlapping the third emission area, and emitting a third light, and a photo detector disposed on the substrate and overlapping the sensing area, wherein the first organic light-emitting diode includes a first pixel electrode, a first lower emission layer disposed on the first pixel electrode, a first upper emission layer disposed on the first lower emission layer, and an opposite electrode disposed on the first upper emission layer, the second organic light-emitting diode includes a second pixel electrode, a second lower emission layer disposed on the second pixel electrode, a second upper emission layer disposed on the second lower emission layer, and the opposite electrode disposed on the second upper emission layer, the third organic light-emitting diode includes a third pixel electrode, a third lower emission layer disposed on the third pixel electrode, a third upper emission layer disposed on the third lower emission layer, and the opposite electrode disposed on the third upper emission layer, and the photo detector includes a fourth pixel electrode, an active layer disposed on the fourth pixel electrode, and the opposite electrode disposed on the active layer.

The display apparatus may further include a charge generation layer disposed on the first lower emission layer, the second lower emission layer, and the third lower emission layer and simultaneously disposed under the first upper emission layer, the second upper emission layer, and the third upper emission layer.

The active layer may include a lower active layer and an upper active layer disposed on the lower active layer, the lower active layer may be arranged on the same layer as the first lower emission layer, the second lower emission layer, and the third lower emission layer, and the upper active layer may be arranged on the same layer as the first upper emission layer, the second upper emission layer, and the third upper emission layer.

Wavelength ranges of detectable light in the lower active layer and the upper active layer may be different from each other.

The display apparatus may further include a near-infrared ray emitting portion configured to emit near-infrared rays having a wavelength greater than or equal to about 750 nm and less than or equal to about 1000 nm.

The near-infrared ray emitting portion may be arranged on a lower surface of the substrate.

The lower active layer may absorb near-infrared rays having a wavelength greater than or equal to about 750 nm and less than or equal to about 1000 nm, and the upper active layer may absorb visible rays having a wavelength greater than or equal to about 495 nm and less than or equal to about 570 nm.

The lower active layer and the upper active layer may absorb visible rays having a wavelength greater than or equal to about 495 nm and less than or equal to about 570 nm.

The charge generation layer may be arranged between the lower active layer and the upper active layer to overlap the sensing area.

The first pixel electrode, the second pixel electrode, the third pixel electrode, and the fourth pixel electrode may be spaced apart from each other, the charge generation layer may include a first charge generation layer overlapping the first pixel electrode, a second charge generation layer overlapping the second pixel electrode, a third charge generation layer overlapping the third pixel electrode, and a fourth charge generation layer overlapping the fourth pixel electrode, and the first charge generation layer, the second charge generation layer, the third charge generation layer, and the fourth charge generation layer may be spaced apart from each other.

The charge generation layer may extend and may be disposed over an entirety of the substrate to overlap each of the first pixel electrode, the second pixel electrode, the third pixel electrode, and the fourth pixel electrode.

The display apparatus may further include a first common layer disposed on the first pixel electrode, the second pixel electrode, the third pixel electrode, and the fourth pixel electrode and under the first lower emission layer, the second lower emission layer, and the third lower emission layer, a second common layer disposed on the first lower emission layer, the second lower emission layer, and the third lower emission layer and under the charge generation layer, a third common layer disposed on the charge generation layer and under the first upper emission layer, the second upper emission layer, and the third upper emission layer, and a fourth common layer disposed on the first upper emission layer, the second upper emission layer, and the third upper emission layer and under the opposite electrode.

In the sensing area, the active layer may be disposed on the first common layer, the second common layer may be disposed on the active layer, and the opposite electrode may be disposed on the second common layer, and the third common layer and the fourth common layer may be arranged in an area except the sensing area.

In the sensing area, the third common layer may be disposed on the substrate, the active layer may be disposed on the third common layer, the fourth common layer may be disposed on the active layer, and the opposite electrode may be disposed on the fourth common layer, and the first common layer and the second common layer may be arranged in an area except the sensing area.

In the sensing area, the lower active layer may be disposed on the first common layer, the second common layer may be disposed on the lower active layer, the charge generation layer may be disposed on the second common layer, the third common layer may be disposed on the charge generation layer, the upper active layer may be disposed on the third common layer, the fourth common layer may be disposed on the upper active layer, and the opposite electrode may be disposed on the fourth common layer.

In the sensing area, the lower active layer may be disposed on the first common layer, the second common layer may be disposed on the lower active layer, the charge generation layer may be disposed on the second common layer, the third common layer may be disposed on the charge generation layer, the upper active layer may be disposed on the third common layer, the fourth common layer may be disposed on the upper active layer, and the opposite electrode may be disposed on the fourth common layer.

When viewed in a direction perpendicular to the substrate, the first emission area and the third emission area may be alternately arranged in a first column, the second emission area may be repeatedly arranged in a second column parallel to the first column, the first column and the second column may be alternately arranged, and the sensing area may be arranged between the second emission areas that are adjacent to each other.

When viewed in a direction perpendicular to the substrate, a distance between the first emission area and the third emission area may be narrower than a distance between the second emission area and the first emission area and a distance between the second emission area and the third emission area, and the sensing area may be located in an area between the first emission area and the second emission area or between the third emission area and the second emission area.

When viewed in a direction perpendicular to the substrate, the first emission area and the third emission area may be arranged side by side to form a first configuration, the second emission area may be located between adjacent first configurations, a distance between the first emission area and the third emission area may be narrower than a distance between the second emission area and the first emission area and a distance between the second emission area and the third emission area, and the sensing area may be located between the first emission area and the second emission area or between the third emission area and the second emission area.

The charge generation layer may include an n-type charge generation layer and a p-type charge generation layer disposed on the n-type charge generation layer.

The display apparatus may further include an auxiliary layer arranged between the first upper emission layer and the third common layer, between the second upper emission layer and the third common layer, or between the third upper emission layer and the third common layer, wherein each of the first upper emission layer, the second upper emission layer, and the third upper emission layer may contact the auxiliary layer.

A thickness of each of the lower active layer and the upper active layer may be between about 300 Å and about 700 Å.

The active layer may have a double-layer structure that includes a p-type semiconductor layer including a p-type organic semiconductor and an n-type semiconductor layer including an n-type organic semiconductor.

The active layer may include a mixed layer in which a p-type organic semiconductor is mixed with an n-type organic semiconductor.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a portion of a display apparatus according to an embodiment;

FIG. 2 is an equivalent circuit diagram of a pixel circuit electrically connected to a display element included in a pixel of the display apparatus of FIG. 1;

FIG. 3 is a schematic cross-sectional view of a display apparatus according to an embodiment;

FIG. 4 is a schematic plan view of an enlarged region “A” of FIG. 1;

FIG. 5 is a schematic cross-sectional view of a display apparatus of FIG. 4, taken along line I-I′ of FIG. 4;

FIG. 6 is a schematic conceptual view of a portion of a display apparatus according to an embodiment;

FIG. 7 is a schematic cross-sectional view of a display apparatus according to another embodiment;

FIG. 8 is a schematic cross-sectional view of a display apparatus according to another embodiment;

FIG. 9 is a schematic cross-sectional view of a display apparatus according to another embodiment;

FIG. 10 is a schematic cross-sectional view of a display apparatus according to another embodiment;

FIG. 11 is a schematic plan view of a portion of a display apparatus according to another embodiment;

FIG. 12 is a schematic plan view of a portion of a display apparatus according to another embodiment; and

FIG. 13 is a schematic plan view of a portion of a display apparatus according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, particular embodiments will be shown in the drawings and described in detail in the written description. The attached drawings for illustrating embodiments of the present disclosure are referred to in order to gain a sufficient understanding of the present disclosure, the merits thereof, and the objectives accomplished by the implementation of the present disclosure. The disclosure may, however, be embodied in many different forms and should not be construed as being limited to the embodiments set forth herein.

One or more embodiments of the present disclosure will be described more fully with reference to the accompanying drawings, like reference numerals in the drawings denote like elements, and repeated descriptions thereof will not be provided.

It will be understood that although the terms “first,” “second,” etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being “formed on” another layer, region, or element, it can be directly or indirectly formed on the other layer, region, or element. That is, for example, intervening layers, regions, or elements may be present.

Sizes of elements in the drawings may be exaggerated or reduced for convenience of explanation. In other words, since sizes and thicknesses of elements in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

It will be understood that when a layer, region, or component is referred to as being connected to another layer, region, or component, it can be directly or indirectly connected to the other layer, region, or component. For example, when a layer, region, or component is referred to as being electrically connected to another layer, region, or component, it can be directly or indirectly electrically connected to the other layer, region, or component.

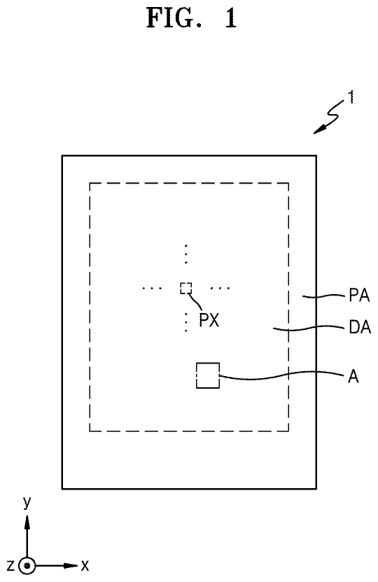

FIG. 1 is a schematic plan view of a portion of a display apparatus according to an embodiment.

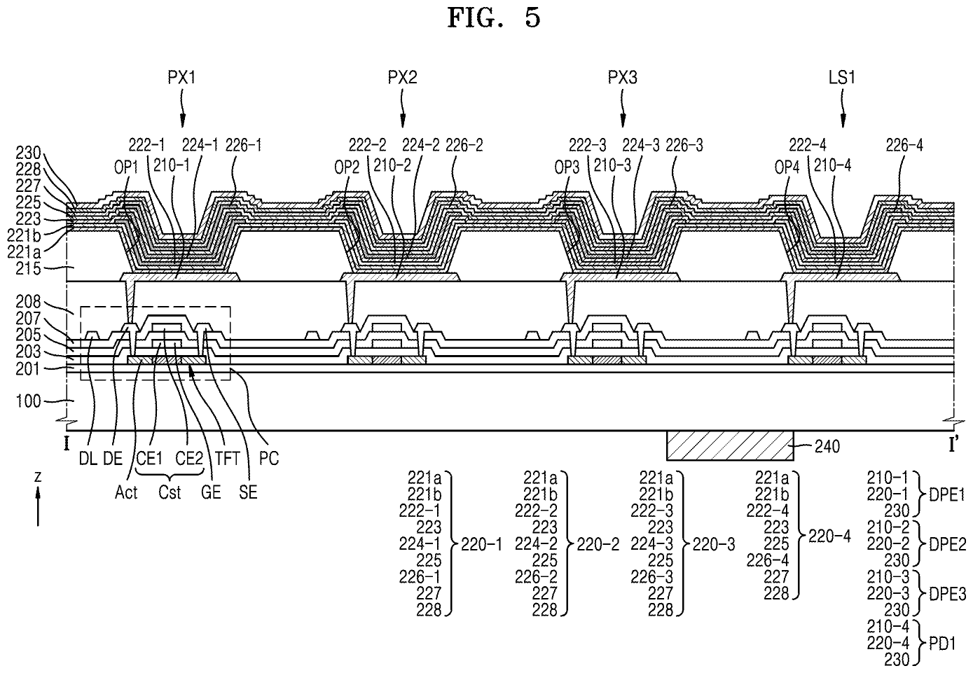

As shown in FIG. 1, a display apparatus 1 may include a display area DA, where pixels PX are arranged, and a peripheral area PA arranged on an outer side of the display area DA. In detail, the peripheral area PA may entirely surround the display area DA. It may be understood that a substrate (100, see FIG. 5) of the display apparatus 1 includes the display area DA and the peripheral area PA.

Each of the pixels PX of the display apparatus 1 is a minimum unit for displaying an image, and the display apparatus 1 may display desired images through a combination of the pixels PX. In detail, each pixel PX may emit a certain color of light, and the display apparatus 1 may display desired images by using light emitted from the pixels PX. For example, each pixel PX may emit red light, green light, or blue light. Each pixel PX may include a display element, such as an organic light-emitting diode. Such a pixel PX may be connected to a pixel circuit including a thin-film transistor TFT, a storage capacitor, and the like.

The display area DA may have a polygonal shape including a rectangular shape, as shown in FIG. 1. For example, the display area DA may have a rectangular shape in which a horizontal length is greater than a vertical length or the horizontal length is less than the vertical length, or may have a square shape. Alternatively, the display area DA may have various shapes, such as an oval shape or a circular shape.

The peripheral area PA may be a non-display area where no pixels PX are arranged. In the peripheral area PA, drivers or the like configured to provide electrical signals or power to the pixels PX may be arranged. In the peripheral area PA, pads (not shown) that may be electrically connected to various electronic components, a printed circuit board, or the like may be arranged. The pads may be spaced apart from each other in the peripheral area PA and electrically connected to a printed circuit board or an integrated circuit device.

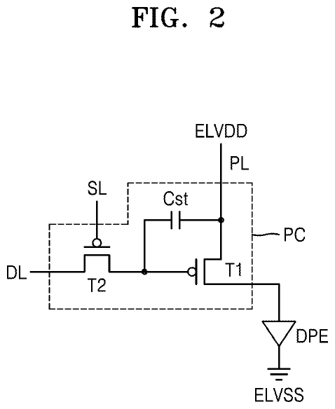

FIG. 2 is an equivalent circuit diagram of a pixel circuit electrically connected to a display element included in a pixel of the display apparatus 1 of FIG. 1.

A pixel circuit PC may include a first transistor T1, a second transistor T2, and a storage capacitor Cst. The second transistor T2 may be a switching transistor, connected to a scan line SL and a data line DL, and turned on in response to a switching signal input through the scan line SL, thereby being configured to transmit a data signal, which is input through the data line DL, to the first transistor T1. An end of the storage capacitor Cst may be electrically connected to the second transistor T2, and the other end thereof may be electrically connected to a driving power line PL, and the storage capacitor Cst may store a voltage corresponding to a difference between a voltage from the second transistor T2 and a driving power voltage ELVDD supplied to the driving power line PL.

The first transistor T1 may be a driving transistor, connected to the driving power line PL and the storage capacitor Cst, and configured to control an intensity of a driving current flowing towards a display element DPE from the driving power line PL according to the voltage stored in the storage capacitor Cst. The display element DPE may emit light having a certain brightness because of the driving current. An opposite electrode of the display element DPE may receive an electrode power voltage ELVSS.

FIG. 2 shows that the pixel circuit PC includes two transistors and one storage capacitor, but one or more embodiments are not limited thereto. For example, the number of transistors or the number of storage capacitors may vary depending on the design of the pixel circuit PC.

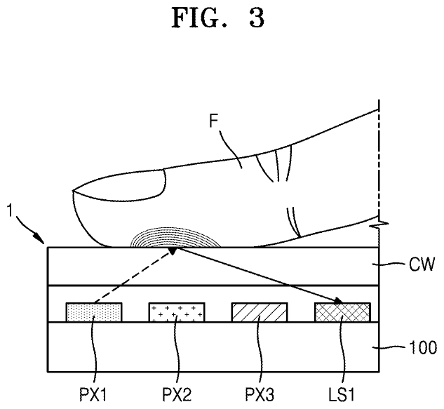

FIG. 3 is a schematic cross-sectional view of a display apparatus according to an embodiment.

Referring to FIG. 3, the display apparatus 1 may include a first pixel PX1, a second pixel PX2, a third pixel PX3, and a first photo detector LS1. The first pixel PX1, the second pixel PX2, and the third pixel PX3 may each include a display element, and the first photo detector LS1 may include a light-receiving element.

In an embodiment, the first pixel PX1 may emit light of a first color, the second pixel PX2 may emit light of a second color, and the third pixel PX3 may emit light of a third color. In this case, the light having the first color, the light having the second color, and the light having the third color may be red light, green light, and blue light, respectively. However, one or more embodiments are not limited thereto. For example, the display apparatus 1 may emit light in full colors. When mixed light of light having a first color, light having a second color, and light having a third color may be white light, the light having the first color, the light having the second color, and the light having the third color are not limited to red light, green light, and blue light. That is, the display apparatus 1 may include the first photo detector LS1, the first pixel PX1, the second pixel PX2, and the third pixel PX3 and may be a full-color display apparatus having a light-detecting function.

As shown in FIG. 3, the display apparatus 1 may have a function of sensing an object, e.g., a fingerprint of a finger F, which is in contact with a cover window CW. As at least a portion of light reflected from a fingerprint of a user from among light emitted from at least one of the first pixel PX1, the second pixel PX2, and the third pixel PX3 is incident to the first photo detector LS1 again, the first photo detector LS1 may detect the reflected light. For example, as green light emitted from the first pixel PX1 is reflected from an object contacting the cover window CW and incident again to the first photo detector LS1, the first photo detector LS1 may detect the green light that is incident again.

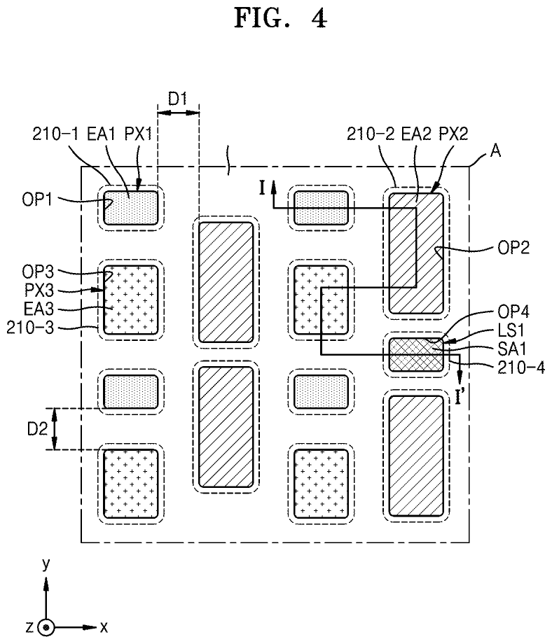

FIG. 4 is a schematic plan view of a portion of the display apparatus 1 according to an embodiment. In detail, FIG. 4 is a schematic plan view of an enlarged region “A” of FIG. 1. FIG. 4 is a plan view on a bank layer 215 for convenience.

As shown in FIG. 4, the display apparatus 1 may include pixels and photo detectors. The pixels may include the first pixels PX1, the second pixels PX2, and the third pixels PX3, and the photo detector may include the first photo detector LS1. The first pixel PX1, the second pixel PX2, and the third pixel PX3 may be pixels emitting different colors of light. For example, the first pixel PX1 may be a pixel emitting red light, the second pixel PX2 may be a pixel emitting blue light, and the third pixel PX3 may be a pixel emitting green light. The red light may be in a wavelength band ranging from about 580 nm to about 780 nm, the blue light may be in a wavelength band ranging from about 400 nm to about 495 nm, and the green light may be in a wavelength band ranging from about 495 nm to about 580 nm. The first photo detector LS1 may detect light emitted from the first pixel PX1, the second pixel PX2, and the third pixel PX3 and reflected from an object, and thus may sense the object.

Each pixel may include a display element, and each photo detector may include a light-receiving element. The display element may be a first display element (DPE1, see FIG. 5), a second display element (DPE2, see FIG. 5), or a third display element (DPE3, see FIG. 5), and the light-receiving element may be a first light-receiving element (PD1, see FIG. 5). In detail, the first pixel PX1 may include the first display element DPE1, the second pixel PX2 may include the second display element DPE2, the third pixel PX3 may include the third display element DPE3, and the first photo detector LS1 may include the first light-receiving element (PD1, see FIG. 5). The display element and the light-receiving element may each include a pixel electrode, an opposite electrode, and an intermediate layer arranged therebetween.

Accordingly, the first pixel PX1 may include a first pixel electrode 210-1, the second pixel PX2 may include a second pixel electrode 210-2, the third pixel PX3 may include a third pixel electrode 210-3, and the first photo detector LS1 may include a fourth pixel electrode 210-4. The first pixel electrode 210-1, the second pixel electrode 210-2, the third pixel electrode 210-3, and the fourth pixel electrode 210-4 may be spaced apart from each other over a substrate (100, see FIG. 5). In the present specification, the expression “in the plane” may indicate a plane viewed in a direction perpendicular to the substrate 100. That is, the expression “A and B spaced apart from each other in the plane” may indicate “A and B spaced apart from each other when viewed in a direction perpendicular to the substrate 100.”

The bank layer 215 may be disposed on the first pixel electrode 210-1, the second pixel electrode 210-2, the third pixel electrode 210-3, and the fourth pixel electrode 210-4. Further, the bank layer 215 may cover edges of each of the first pixel electrode 210-1, the second pixel electrode 210-2, the third pixel electrode 210-3, and the fourth pixel electrode 210-4. That is, a first opening OP1 exposing a central portion of the first pixel electrode 210-1, a second opening OP2 exposing a central portion of the second pixel electrode 210-2, a third opening OP3 exposing a central portion of the third pixel electrode 210-3, and a fourth opening OP4 exposing a central portion of the fourth pixel electrode 210-4 are defined in the bank layer 215.

Although not shown in FIG. 4, each of emission layers emitting light may be arranged in the first opening OP1, the second opening OP2, and the third opening OP3 of the bank layer 215 respectively, and each of active layers for detecting light may be arranged in the fourth opening OP4 of the bank layer 215. The opposite electrodes may be disposed on the emission layers and the active layers. As described above, a stack structure of the pixel electrode, the emission layer, and the opposite electrode may form one display element. Also, as described above, a stack structure of the pixel electrode, the active layer, and the opposite electrode may form one light-receiving element. One opening of the bank layer 215 may correspond to one display element and define one emission area. Alternatively, one opening of the bank layer 215 may correspond to one light-receiving element and define one sensing area.

For example, an emission layer emitting red light may be arranged in the first opening OP1, and the first pixel PX1 may include a first emission area EA1 defined by the first opening OP1. Similarly, an emission layer emitting blue light may be arranged in the second opening OP2, and the second pixel PX2 may include a second emission area EA2 defined by the second opening OP2. Similarly, an emission layer emitting green light may be arranged in the third opening OP3, and the third pixel PX3 may include a third emission area EA3 defined by the third opening OP3. Similarly, an active layer for detecting light may be arranged in the fourth opening OP4, and the first photo detector LS1 may include a first sensing area SA1 defined by the fourth opening OP4.

The first emission area EA1 may be defined by the first opening OP1, the second emission area EA2 may be defined by the second opening OP2, the third emission area EA3 may be defined by the third opening OP3, and the first sensing area SA1 may be defined by the fourth opening OP4. Accordingly, an area of the first opening OP1 may be the same as that of the first emission area EA1, an area of the second opening OP2 may be equal to that of the second emission area EA2, and an area of the third opening OP3 may be equal to that of the third emission area EA3. An area of the fourth opening OP4 may be equal to that of the first sensing area SA1. Also, a distance between the first opening OP1 and the second opening OP2 may be equal to a distance between the first emission area EA1 and the second emission area EA2. A distance between the first opening OP1 and the third opening OP3 may be equal to a distance between the first emission area EA1 and the third emission area EA3, and a distance between the second opening OP2 and the third opening OP3 may be equal to a distance between the second emission area EA2 and the third emission area EA3. As described, a distance between the second opening OP2 and the fourth opening OP4 may be equal to a distance between the second emission area EA2 and the first sensing area SA1.

In a plane, the first pixels PX1 and the third pixels PX3 may be alternately arranged in a first column in a first direction (e.g., a y-direction). That is, the first emission areas EA1 and the third emission areas EA3 may be alternately arranged in the first column along the y-direction. As described, the second pixels PX2 may be repeatedly arranged in a second column in the first direction (e.g., the y-direction). That is, the second emission areas EA2 may be repeatedly arranged in the second column along the y-direction. The first column and the second column may be arbitrarily determined and alternately arranged in a second direction (e.g., an x-direction) perpendicular to the first direction. In one case, the first photo detector LS1 may be arranged between the second pixels PX2 that are repeatedly arranged in the second column along the y-direction. That is, the first sensing area SA1 may be arranged between the second emission areas EA2 that are adjacent to each other. In another case, the second pixels PX2 may be repeatedly arranged in the second column along the y-direction without the first photo detector LS1.

When viewed in a direction perpendicular to the substrate 100 (a z-axis direction), each of the first opening OP1, the second opening OP2, the third opening OP3, and the fourth opening OP4 may have a polygonal shape. In other words, when viewed in the direction perpendicular to the substrate 100 (the z-axis direction), each of the first emission area EA1, the second emission area EA2, the third emission area EA3, and the first sensing area SA1 may have the same polygonal shape. FIG. 4 shows that, when viewed in the direction perpendicular to the substrate 100 (the z-axis direction), a shape of each of the first emission area EA1, the second emission area EA2, the third emission area EA3, and the first sensing area SA1 is a rectangle, specifically, a rectangle with rounded edges. However, one or more embodiments are not limited thereto. For example, when viewed in the direction perpendicular to the substrate 100 (the z-axis direction), each of the first emission area EA1, the second emission area EA2, the third emission area EA3, and the first sensing area SA1 may have a circular shape or an oval shape.

Areas of the first opening OP1, the second opening OP2, the third opening OP3, and the fourth opening OP4 may be different from each other. In particular, as shown in FIG. 4, the area of the second opening OP2 may be less than that of the third opening OP3. The area of the first opening OP1 may be less than or the same as the area of the third opening OP3. The area of the fourth opening OP4 may be less than that of the third opening OP3. In other words, the areas of the first emission area EA1, the second emission area EA2, the third emission area EA3, and the first sensing area SA1 may be different from each other. In detail, the area of the second emission area EA2 may be less than that of the third emission area EA3. The area of the first emission area EA1 may be less than or the same as the area of the third emission area EA3. The area of the first sensing area SA1 may be less than the area of the third emission area EA3. However, the areas of the first emission area EA1, the second emission area EA2, the third emission area EA3, and the first sensing area SA1 are not limited thereto.

Distances between each of the pixels PX may differ. In detail, the second pixel PX2 may be spaced apart from the first pixel PX1 by as much as a first distance D1, and the third pixel PX3 may be spaced apart from the first pixel PX1 by as much as a second distance D2. The first distance D1 may be greater than the second distance D2. In the present disclosure, the distance between the pixels PX indicates a distance between emission areas of the pixels PX. In other words, the distance between two adjacent pixels PX indicates a distance between two adjacent openings defining the emission areas. In detail, the distance between two adjacent pixels PX indicates a distance from one side of a first opening to one side of a second opening that is adjacent to the first opening. In detail, the distance between two adjacent pixels PX indicates a distance from one side of a first emission area to one side of a second emission area that is adjacent to the first emission area.

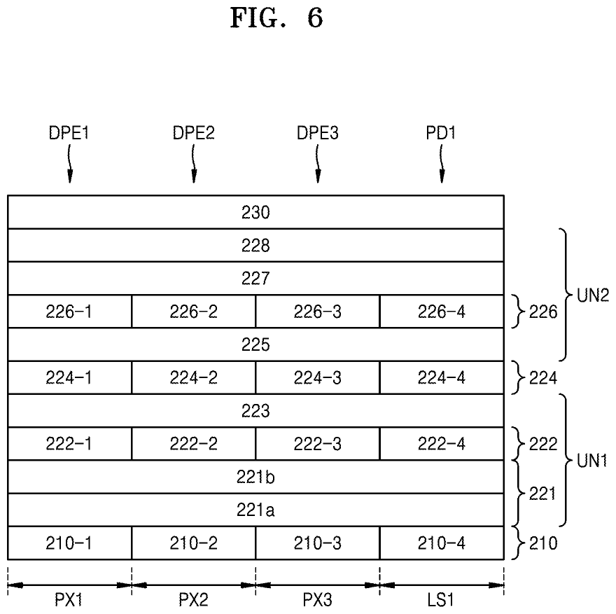

FIG. 5 is a schematic cross-sectional view of a portion of a display apparatus according to an embodiment. In detail, FIG. 5 is a schematic cross-sectional view of the display apparatus of FIG. 4, taken along line I-I′ of FIG. 4. FIG. 6 is a schematic conceptual view of a portion of a display apparatus according to an embodiment. In detail, FIG. 6 is a schematic cross-sectional view of a stack structure of display elements and light-receiving elements of the display apparatus, according to an embodiment.

As shown in FIG. 5, the display apparatus 1 may include the substrate 100. The substrate 100 may include various materials that are flexible or bendable. For example, the substrate 100 may include glass, metals, or polymer resin. For example, the substrate 10 may include polymer resin, such as polyethersulphone, polyacrylate, polyetherimide, polyethylene naphthalate, polyethylene terephthalate, polyphenylene sulfide, polyarylate, polyimide, polycarbonate, or cellulose acetate propionate. Various modifications may be made to the substrate 100, and for example, the substrate 100 may have a multilayered structure that includes two layers including the above polymer resin and a barrier layer including an inorganic material (e.g., silicon oxide, silicon nitride, silicon oxynitride, or the like) and arranged between the layers.

A display element DPE, a light-receiving element PD, and a pixel circuit PC may be disposed over the substrate 100. The pixel circuit PC may be electrically connected to the display element DPE. In detail, the first pixel PX1, the second pixel PX2, the third pixel PX3, and the first photo detector LS1 may be disposed on the substrate 100. Each of the first pixel PX1, the second pixel PX2, and the third pixel PX3 may include the display element DPE, and each of the first photo detectors LS1 may include the light-receiving element PD. The display element DPE may be the first display element DPE1, the second display element DPE2, or the third display element DPE3 Also, the light-receiving element PD may be the first light-receiving element PD1. That is, the first pixel PX1 may include the first display element DPE1, the second pixel PX2 may include the second display element DPE2, the third pixel PX3 may include the third display element DPE3, and the first photo detector LS1 may include the first light-receiving element PD1.

As the first display element DPE1, the second display element DPE2, and the third display element DPE3 are electrically connected to the pixel circuit PC, the emission thereof may be controlled. Also, the light detection may be controlled as the first light-receiving element PD1 is electrically connected to the pixel circuit PC. Because the structures of the pixel circuits PC respectively electrically connected to the first display element DPE1, the second display element DPE2, the third display element DPE3, and the first light-receiving element PD1 are the same, one pixel circuit PC is mainly described hereinafter. The pixel circuit PC includes thin-film transistors TFT and a storage capacitor Cst. For the convenience of illustration, FIG. 5 shows a thin-film transistor TFT, and such a thin-film transistor TFT may correspond to the first transistor (T1, see FIG. 2) described above.

A buffer layer 201 may be arranged between the thin-film transistor TFT and the substrate 100, the buffer layer 201 including an inorganic material, such as silicon oxide, silicon nitride, and/or silicon oxynitride. The buffer layer 201 may increase the flatness of an upper surface of the substrate 100 or may prevent or decrease the penetration of impurities to a semiconductor layer Act of the thin-film transistor TFT from the substrate 100, etc.

As shown in FIG. 5, the thin-film transistor TFT may include the semiconductor layer Act including amorphous silicon, polycrystalline silicon, an organic semiconductor material, or an oxide semiconductor material. The thin-film transistor TFT may include a gate electrode GE, a source electrode SE, and/or a drain electrode DE. The gate electrode GE may include various conductive materials and have various layer structures including, for example, a molybdenum (Mo) layer and an aluminum (Al) layer. Alternatively, the gate electrode GE may include a TiNx layer, an Al layer, and/or a Ti layer. The source electrode SE and the drain electrode DE may also include various conductive materials and have various layer structures including, for example, a Ti layer, an Al layer, and/or a copper (Cu) layer.

A gate insulating layer 203 including an inorganic material, such as silicon oxide, silicon nitride, and/or silicon oxynitride, may be arranged between the semiconductor layer Act and the gate electrode GE to insulate the semiconductor layer Act from the gate electrode GE. FIG. 5 shows that the gate insulating layer 203 has a shape corresponding to the entire substrate 100 and a structure in which contact holes are formed in predetermined portions, but one or more embodiments are not limited thereto. For example, the gate insulating layer 203 may be patterned in a shape that is the same as that of the gate electrode GE.

In addition, a first interlayer insulating layer 205 including an inorganic material, such as silicon oxide, silicon nitride, and/or silicon oxynitride, may be disposed on the gate electrode GE. The first interlayer insulating layer 205 may have a single-layer structure or a multilayered structure including the above material. An insulating layer including the above inorganic material may be formed through Chemical Vapor Deposition (CVD) or Atomic Layer Deposition (ALD), which is also applied to the embodiments below and modified examples.

The storage capacitor Cst may include a first electrode CE1 and a second electrode CE2 that overlap each other with respect to the first interlayer insulating layer 205 therebetween. The storage capacitor Cst may overlap the thin-film transistor TFT. In this regard, FIG. 4 shows that the gate electrode GE of the thin-film transistor TFT is the first electrode CE1 of the storage capacitor Cst, but one or more embodiments are not limited thereto. For example, the storage capacitor Cst may not overlap the thin-film transistor TFT. The second electrode CE2 of the storage capacitor Cst may include a conductive material including Mo, Al, Cu, titanium (Ti), or the like and may be a layer or layers including such materials.

A second interlayer insulating layer 207 may be disposed on the second electrode CE2 of the storage capacitor Cst, the second interlayer insulating layer 207 including an inorganic material, such as silicon oxide, silicon nitride, and/or silicon oxynitride. The second interlayer insulating layer 207 may have a single-layer structure or a multilayered structure including the above material.

The source electrode SE and the drain electrode DE may be arranged on the second interlayer insulating layer 207. A data line DL may be arranged on the same layer and include the same material as the source electrode SE and the drain electrode DE. The source electrode SE, the drain electrode DE, and the data line DL may include materials with excellent conductivity. The source electrode SE and the drain electrode DE may each include a conductive material including Mo, Al, Cu, or Ti and may each be a layer or layers including the above material. For example, the source electrode SE, the drain electrode DE, and the data line DL may each have a multilayered structure of Ti/Al/Ti.

However, one or more embodiments are not limited thereto. For example, the thin-film transistor TFT may include any one of the source electrode SE and the drain electrode DE or may not include the source electrode SE and the drain electrode DE. For example, one thin-film transistor TFT may not include a drain electrode DE, another thin-film transistor TFT connected to the one thin-film transistor TFT may not include a source electrode SE, and semiconductor layers Act of the thin-film transistors TFT may be connected to each other. Such a connection structure may bring the same effect as the effect achieved when one thin-film transistor TFT includes a source electrode SE, another thin-film transistor TFT includes a drain electrode DE, and the source electrode SE of the one thin-film transistor TFT is connected to the drain electrode DE of the other thin-film transistor TFT.

As shown in FIG. 5, a planarization layer 208 may be arranged to cover the thin-film transistor TFT and the storage capacitor Cst. The planarization layer 208 may include an organic insulating material. For example, the planarization layer 208 may include photoresist, benzocyclobutene (BCB), polyimide, hexamethyldisiloxane (HMDSO), polymethylmethacrylate (PMMA), polystyrene, a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, or any blend thereof. Although not shown in FIG. 5, a third interlayer insulating layer (not shown) may be further disposed under the planarization layer 208. The third interlayer insulating layer may include an inorganic insulating material, such as silicon oxide, silicon nitride, or silicon oxynitride.

A near-infrared ray emitting portion 240 may be additionally disposed under the substrate 100. That is, the near-infrared ray emitting portion 240 is disposed opposite to the display element DPE, the light-receiving element PD, and the pixel circuit PC. The near-infrared ray emitting portion 240 may emit near-infrared rays having a wavelength greater than or equal to about 750 nm and less than or equal to about 1000 nm. The near-infrared ray emitting portion 240 may include a piezoelectric element for emitting near-infrared rays, or the like and may be externally formed on the display apparatus 1. Because light in a near-infrared band which is emitted from the near-infrared ray emitting portion 240 has long wavelengths and higher transmittance than visible rays, the light may penetrate outside and inside the skin of a finger, and thus, ridges and valleys of an object, e.g., a finger, may be accurately recognized. Also, the light in the near-infrared band which is emitted from the near-infrared ray emitting portion 240 may penetrate organic materials and may not be greatly affected by visible rays, wherein examples of the influences of the visible rays may include degradation in rectilinear propagation of light because of a decrease in light intensity or light refraction. However, the location of the near-infrared ray emitting portion 240 is not limited to a bottom portion of the substrate 100, and the near-infrared ray emitting portion 240 may be arranged on the same layer as a display element. Also, the description that the near-infrared ray emitting portion 240 is arranged on the bottom portion of the substrate 100 may include that the near-infrared ray emitting portion 240 is embedded in the substrate 100.

On the planarization layer 208, the first display element DPE1, the second display element DPE2, the third display element DPE3, and the first light-receiving element PD1 may be spaced apart from each other. The first display element DPE1, the second display element DPE2, and the third display element DPE3 may emit different colors of light. For example, the first display element DPE1 may emit red light, the second display element DPE2 may emit blue light, and the third display element DPE3 may emit green light. The first light-receiving element PD1 may detect light emitted from the display elements DPE or the near-infrared ray emitting portion 240 and reflected from the object.

The first display element DPE1 may include the first pixel electrode 210-1, a first intermediate layer 220-1, and an opposite electrode 230. The second display element DPE2 may include the second pixel electrode 210-2, a second intermediate layer 220-2, and the opposite electrode 230. The third display element DPE3 may include the third pixel electrode 210-3, a third intermediate layer 220-3, and the opposite electrode 230. The first light-receiving element PD1 may include the fourth pixel electrode 210-4, a fourth intermediate layer 220-4, and the opposite electrode 230. That is, the first pixel electrode 210-1, the second pixel electrode 210-2, the third pixel electrode 210-3, and the fourth pixel electrode 210-4, which are respectively included in the first display element DPE1, the second display element DPE2, the third display element DPE3, and the first light-receiving element PD1, may be respectively patterned and included. The opposite electrode 230 of the first display element DPE1, the second display element DPE2, the third display element DPE3, and the first light-receiving element PD1 may be integrally arranged over the first display element DPE1, the second display element DPE2, the third display element DPE3, and the first light-receiving element PD1 as a single body. The first intermediate layer 220-1, the second intermediate layer 220-2, the third intermediate layer 220-3, and the fourth intermediate layer 220-4 may be respectively arranged between the opposite electrode 230 and the first pixel electrode 210-1, the second pixel electrode 210-2, the third pixel electrode 210-3, and the fourth pixel electrode 210-4.

The first pixel electrode 210-1, the second pixel electrode 210-2, the third pixel electrode 210-3, and the fourth pixel electrode 210-4 may be spaced apart from each other on the substrate 100. Each of the first pixel electrode 210-1, the second pixel electrode 210-2, the third pixel electrode 210-3, and the fourth pixel electrode 210-4 may include a light-transmissive conductive layer including light-transmissive conductive oxide, such as ITO, In₂O₃, or IZO, and a reflection layer including metal, such as Al or silver (Ag). For example, the first pixel electrode 210-1, the second pixel electrode 210-2, the third pixel electrode 210-3, and the fourth pixel electrode 210-4 may each have a three-layer structure of ITO/Ag/ITO.

As shown in FIG. 5, the first pixel electrode 210-1, the second pixel electrode 210-2, the third pixel electrode 210-3, and the fourth pixel electrode 210-4 may contact any one of the source electrode SE and the drain electrode DE, and also be electrically connected to the thin-film transistor TFT. In detail, each of the first pixel electrode 210-1, the second pixel electrode 210-2, the third pixel electrode 210-3, and the fourth pixel electrode 210-4 may contact any one of the source electrode SE and the drain electrode DE through a contact hole formed in the planarization layer 208.

The bank layer 215 may be disposed on the planarization layer 208. Because an opening corresponding to the pixel PX and the photo detector LS is defined in the bank layer 215, that is, an opening exposing at least a central portion of the pixel electrode, the bank layer 215 may define the emission area EA and the sensing area SA. In detail, the bank layer 215 may include the first opening OP1, the second opening OP2, the third opening OP3, and the fourth opening OP4. The first opening OP1 may expose a central portion of the first pixel electrode 210-1, the second opening OP2 may expose a central portion of the second pixel electrode 210-2, and the third opening OP3 may expose a central portion of the third pixel electrode 210-3. Also, as shown in FIG. 5, the bank layer 215 may increase a distance between edges of the first pixel electrode 210-1 and the opposite electrode 230 disposed over the first pixel electrode 210-1. Similarly, the bank layer 215 may increase a distance between edges of the second pixel electrode 210-2 and the opposite electrode 230, a distance between edges of the third pixel electrode 210-3 and the opposite electrode 230, and a distance between edges of the fourth pixel electrode 210-4 and the opposite electrode 230. Thus, arcs, etc. may be prevented from being generated on the edges of the first pixel electrode 210-1, the second pixel electrode 210-2, the third pixel electrode 210-3, or the fourth pixel electrode 210-4. The bank layer 215 may include an organic material, e.g., polyimide, HMDSO, etc.

The opposite electrode 230 may be disposed over the first pixel electrode 210-1. The opposite electrode 230 may be integrally formed over the first display element DPE1, the second display element DPE2, the third display element DPE3, and the first light-receiving element PD1. Therefore, the opposite electrode 230 may also be disposed over the second pixel electrode 210-2, the third pixel electrode 210-3, and the fourth pixel electrode 210-4. The opposite electrode 230 may include a light-transmissive conductive layer including ITO, In₂O₃, or IZO and also a semi-transmissive layer including metal, e.g., Al or Ag. For example, the opposite electrode 230 may be a semi-transmissive layer including magnesium (Mg) or Ag.

The first intermediate layer 220-1 may be arranged between the first pixel electrode 210-1 and the opposite electrode 230. The second intermediate layer 220-2 may be arranged between the second pixel electrode 210-2 and the opposite electrode 230, and the third intermediate layer 220-3 may be arranged between the third pixel electrode 210-3 and the opposite electrode 230. The fourth intermediate layer 220-4 may be arranged between the fourth pixel electrode 210-4 and the opposite electrode 230. That is, the first intermediate layer 220-1 may be disposed on the first pixel electrode 210-1, and the second intermediate layer 220-2 may be disposed on the second pixel electrode 210-2. The third intermediate layer 220-3 may be disposed on the third pixel electrode 210-3, and the fourth intermediate layer 220-4 may be disposed on the fourth pixel electrode 210-4.

As shown in FIG. 6, each of the first display element DPE1, the second display element DPE2, and the third display element DPE3 may have a tandem structure including emission layers. As each of the first display element DPE1, the second display element DPE2, and the third display element DPE3 has a structure in which the emission layers are stacked, the color purity and emission efficiency may be improved. Also, similar to the tandem structures of the first to third display elements DPE1 to DPE3, the first light-receiving element PD1 may include a dual detector structure including a plurality of active layers.

In an embodiment, the first intermediate layer 220-1, the second intermediate layer 220-2, and the third intermediate layer 220-3 respectively included in the first display element DPE1, the second display element DPE2, and the third display element DPE3 may each include emission layers. Also, the fourth intermediate layer 220-4 included in the first light-receiving element PD1 may include active layers. In detail, the first intermediate layer 220-1 may include a first lower emission layer 222-1 and a first upper emission layer 226-1. The first lower emission layer 222-1 may be disposed over the first pixel electrode 210-1, and the first upper emission layer 226-1 may be disposed over the first lower emission layer 222-1 to overlap the same. Similarly, the second intermediate layer 220-2 may include a second lower emission layer 222-2 and a second upper emission layer 226-2. The second lower emission layer 222-2 may be disposed over the second pixel electrode 210-2, and the second upper emission layer 226-2 may be disposed over the second lower emission layer 222-2 to overlap the same. Similarly, the third intermediate layer 220-3 may include a third lower emission layer 222-3 and a third upper emission layer 226-3. The third lower emission layer 222-3 may be disposed over the third pixel electrode 210-3, and the third upper emission layer 226-3 may be disposed over the third lower emission layer 222-3 to overlap the same. Similarly, the fourth intermediate layer 220-4 may include a lower active layer 222-4 and an upper active layer 226-4. The lower active layer 222-4 may be disposed over the fourth pixel electrode 210-4, and the upper active layer 226-4 may be disposed over the lower active layer 222-4 to overlap the same.

The first lower emission layer 222-1, the second lower emission layer 222-2, the third lower emission layer 222-3, and the lower active layer 222-4 may be respectively patterned and included in the first display element DPE1, the second display element DPE2, the third display element DPE3, and the first light-receiving element PD1. Also, the first upper emission layer 226-1, the second upper emission layer 226-2, the third upper emission layer 226-3, and the upper active layer 226-4 may be respectively patterned and included in the first display element DPE1, the second display element DPE2, the third display element DPE3, and the first light-receiving element PD1.

The first display element DPE1 may emit red light, the second display element DPE2 may emit blue light, and the third display element DPE3 may emit green light. To realize such light emission, the first lower emission layer 222-1 and the first upper emission layer 226-1 may emit red light, the second lower emission layer 222-2 and the second upper emission layer 226-2 may emit blue light, and the third lower emission layer 222-3 and the third upper emission layer 226-3 may emit green light. The first lower emission layer 222-1, the second lower emission layer 222-2, and the third lower emission layer 222-3 may form a first unit UN1, and the first upper emission layer 226-1, the second upper emission layer 226-2, and the third upper emission layer 226-3 may form a second unit UN2.

The first light-receiving element PD1 may detect light emitted from the first display element DPE1, the second display element DPE2, the third display element DPE3, and the near-infrared ray emitting portion 240 and reflected from the object. To realize such light detection, the lower active layer 222-4 may detect light in a near-infrared band which is emitted from the near-infrared ray emitting portion 240 and reflected from the object, and the upper active layer 226-4 may detect light in a visible band which is emitted from the first display element DPE1, the second display element DPE2, and the third display element DPE3 and reflected from the object. In detail, the lower active layer 222-4 may absorb near-infrared rays having a wavelength greater than or equal to about 750 nm and less than or equal to about 1000 nm, and the upper active layer 226-4 may absorb light in the visible band, specifically, visible rays included in the green light and having a wavelength greater than or equal to about 495 nm and less than or equal to about 570 nm. That is, wavelength ranges of detectable light by the lower active layer 222-4 and the upper active layer 226-4 may be different from each other. The lower active layer 222-4 may be arranged on substantially the same layer as the first lower emission layer 222-1, the second lower emission layer 222-2, and the third lower emission layer 222-3 described above and thus may form the first unit UN1. The upper active layer 226-4 may be arranged on substantially the same layer as the first upper emission layer 226-1, the second upper emission layer 226-2, and the third upper emission layer 226-3 described above and thus may form the second unit UN2.

That is, as the first light-receiving element PD1 included in the first photo detector LS1 includes the lower active layer 222-4 that absorbs the light in the near-infrared band and the upper active layer 226-4 disposed over the lower active layer 222-4 and absorbing the light in the visible band, the first light-receiving element PD1 may form a dual detector structure. Accordingly, the first photo detector LS1 may primarily absorb short wavelengths in the upper active layer 226-4 that is arranged on a relatively upper portion of the display apparatus and then absorb long wavelengths in the lower active layer 222-4 that is arranged on a relatively lower portion of the display apparatus. In particular, as described above, because the light in the near-infrared band has long wavelengths and the transmittance thereof is higher than that of the light in the visible band, the object may be accurately recognized. Accordingly, the upper active layer 226-4 absorbing the light in the visible band may be used as a fingerprint sensor, and the lower active layer 222-4 absorbing the light in the visible band may be used as a touch sensor. In a display apparatus including a light-receiving element including the lower active layer 222-4, a touch sensor layer, which needs to be separately arranged, may be omitted. As a result, in the display apparatus 1 according to an embodiment, as the upper active layer 226-4, which may be used as a fingerprint sensor, and the lower active layer 222-4, which may be used as a touch sensor, are stacked in the same planar area, a dual sensor may be used without securing an additional sensing area. That is, the planar area may be effectively used in the display apparatus, and the resolution of the display apparatus may increase. In addition, a range of a wavelength detectable by the first photo detector LS1 increases, and thus, the sensing sensitivity and sensing reliability of the first photo detector LS1 may also be improved.

Each of the lower active layer 222-4 and the upper active layer 226-4 may have a thickness ranging from about 200 Å to about 2000 Å. The thickness of each of the lower active layer 222-4 and the upper active layer 226-4 may preferably be between 300 Å and about 700 Å. Also, each of the lower active layer 222-4 and the upper active layer 226-4 may include a p-type organic semiconductor and an n-type organic semiconductor. In this case, the p-type organic semiconductor may function as an electron donor, and the n-type organic semiconductor may function as an electron acceptor. Each of the lower active layer 222-4 and the upper active layer 226-4 may have a dual-layer structure that includes a p-type semiconductor layer including a p-type organic semiconductor and an n-type semiconductor layer including an n-type organic semiconductor. Alternatively, each of the lower active layer 222-4 and the upper active layer 226-4 may be a mixed layer in which a p-type organic semiconductor and an n-type organic semiconductor are mixed. In this case, the lower active layer 222-4 and the upper active layer 226-4 may be formed by co-depositing the p-type organic semiconductor and the n-type organic semiconductor. When the lower active layer 222-4 and the upper active layer 226-4 are mixed layers, excitons may be generated in a diffusion length from a donor-acceptor interface.

In an embodiment, the p-type organic semiconductor may be a compound that functions as an electron donor donating electrons. In detail, the p-type organic semiconductor may be an organic compound having electron donating power. For example, the p-type organic semiconductor may use a metal complex including, as a ligand, a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a naphthalocyanine compound, a cyanine compound, a merocyanine compound, an oxonol compound, a polyamine compound, an indole compound, a pyrrole compound, a pyrazole compound, a polyarylene compound, a condensed aromatic carbocyclic compound (a naphthalene derivative, an anthracene derivative, a phenanthrene derivative, a tetracene derivative, a pyrene derivative, a perylene compound, a fluoranthene compound), and a nitrogen-containing heterocyclic compound, but is not limited thereto.

In an embodiment, the n-type organic semiconductor may be a compound that functions as an electron acceptor accepting electrons. In detail, the n-type organic semiconductor may be an organic compound having electron acceptability. For example, the n-type organic semiconductor may include a metal complex including, as a ligand, fullerene, a fullerene derivative, a condensed aromatic carbocyclic compound (a naphthalene derivative, an anthracene derivative, a phenanthrene derivative, a tetracene derivative, a pyrene derivative, a perylene compound, a fluoranthene compound), a five to seven-membered heterocyclic compound containing nitrogen atoms, oxygen atoms, or sulfur atoms (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purin, triazole pyridazine, triazole pyrimidine, tetrazine dene, oxadiazole, imidazopyridine, pyrrolidine, pyrrolopyridine, thiadiazole pyridine, dibenzazepine, tribenzazepine, etc.), a polyarylene compound, a fluorene compound, a cyclopentadiene compound, a silyl compound, or a nitrogen-containing heterocyclic compound, but is not limited thereto.

Charge generation layers 224-1, 224-2, and 224-3 may be arranged between the first lower emission layer 222-1 and the first upper emission layer 226-1, between the second lower emission layer 222-2 and the second upper emission layer 226-2, and between the third lower emission layer 222-3 and the third upper emission layer 226-3, respectively. As shown in FIG. 5, the charge generation layers 224-1, 224-2, and 224-3 may include a first charge generation layer 224-1 arranged between the first lower emission layer 222-1 and the first upper emission layer 226-1, a second charge generation layer 224-2 arranged between the second lower emission layer 222-2 and the second upper emission layer 226-2, and a third charge generation layer 224-3 arranged between the third lower emission layer 222-3 and the third upper emission layer 226-3. However, the first, second, and third charge generation layers 224-1, 224-2, and 224-3 may not be arranged in the first sensing area (SA1, see FIG. 4). That is, the first, second, and third charge generation layers 224-1, 224-2, and 224-3 may not be arranged between the lower active layer 222-4 and the upper active layer 226-4.

The first charge generation layer 224-1, the second charge generation layer 224-2, and the third charge generation layer 224-3 may overlap the first pixel electrode 210-1, the second pixel electrode 210-2, and the third pixel electrode 210-3, respectively. The first charge generation layer 224-1, the second charge generation layer 224-2, and the third charge generation layer 224-3 may be spaced apart from each other. That is, the first charge generation layer 224-1, the second charge generation layer 224-2, and the third charge generation layer 224-3 may be patterned using a Fine Metal Mask (FMM). As shown in FIG. 5, when the first charge generation layer 224-1, the second charge generation layer 224-2, and the third charge generation layer 224-3 are spaced apart from each other, the occurrence of a leakage current in a lateral direction may be restricted, compared to when the charge generation layer 224 is commonly formed on the entire substrate 100. In addition, the first charge generation layer 224-1, the second charge generation layer 224-2, and the third charge generation layer 224-3, which are patterned, may prevent a mixture of colors because of a leakage current, wherein such mixture may be generated through the charge generation layer 224. However, one or more embodiments are not limited thereto, and the charge generation layer 224 may be commonly generated in the first display element DPE1, the second display element DPE2, and the third display element DPE3. In other words, the first charge generation layer 224-1, the second charge generation layer 224-2, and the third charge generation layer 224-3 may be connected as a single body. In other words, a charge generation layer having the same area as or a greater area than the display area DA to entirely cover the display area DA is formed, and portions of the charge generation layer may correspond to the first charge generation layer 224-1, the second charge generation layer 224-2, and the third charge generation layer 224-3

The charge generation layer 224 may supply charges to the first unit UN1 and the second unit UN2, wherein the first unit UN1 includes the first lower emission layer 222-1, the second lower emission layer 222-2, and the third lower emission layer 222-3, and the second unit UN2 includes the first upper emission layer 226-1, the second upper emission layer 226-2, and the third upper emission layer 226-3. In detail, the charge generation layer 224 may include an n-type charge generation layer nCGL (not shown) for providing electrons to the first unit UN1 and a p-type charge generation layer pCGL (not shown) for providing holes to the second unit UN2. The p-type charge generation layer may be disposed on the n-type charge generation layer and thus contact the same. Accordingly, the emission efficiency of each of the first display element DPE1, the second display element DPE2, and the third display element DPE3 having a structure, in which the emission layers are stacked, may increase.

The n-type charge generation layer nCGL may include an n-type dopant material and an n-type host material. The n-type dopant material may be organic materials, to which Group 1 and Group 2 metals on a periodic table or electrons may be injected, or a mixture thereof. For example, the n-type dopant material may be any one of an alkali metal and an alkali earth metal. That is, the n-type charge generation layer nCGL may include an organic layer doped with an alkali metal such as lithium (Li), sodium (Na), potassium (K), or cesium (Cs), or an alkali earth metal such as Mg, strontium (Sr), barium (Ba), or radium (Ra), but is not limited thereto. The n-type host material may be a material configured to deliver electrons, e.g., any one or more of tris(8-hydroxyquinolino)aluminum (Alq₃), 8-hydroxyquinolinolato-lithium (Liq), 2-(4-biphenylyl)-5-(4-tert-butylphenyl)-1,3,4oxadiazole (PBD), 3-(4-biphenyl)4-phenyl-5-tert-butylphenyl-1,2,4-triazole (TAZ), spiro-PBD, bis(2-methyl-8-quinolinolate)-4-(phenylphenolato)aluminium (BAlq) SAlq, 2,2′,2″-(1,3,5-benzinetriyl)-tris(1-phenyl-1-H-benzimidazole (TPBi), oxadiazole, triazole, phenanthroline, benzoxazole, and benzthiazole, but one or more embodiments are not limited thereto.

The p-type charge generation layer pCGL may include a p-type dopant material and a p-type host material. The p-type dopant material may include metal oxide, an organic material such as 2,3,5,6-tetrafluoro-7,7,8,8-tetracyano-quinodimethane (F4-TCNQ), hexaazatriphenylene-hexacarbonitrile (HAT-CN), or hexaazatriphenylene, or a metallic material such as V₂O₅, MoOx, or WO₃, but is not limited thereto. The p-type host material may include a material configured to deliver holes, for example, any one or more of N,N-dinaphthyl-N,N′-diphenyl benzidine, N,N′-bis(naphthalene-1-yl)-N,N′-bis(phenyl)-2,2′-dimethylbenzidine (NPD), N,N′-bis-(3-methylphenyl)-N,N′-bis-(phenyl)-benzidine (TPD), and 4,4′,4-Tris(N-3-methylphenyl-N-phenyl-amino)-triphenylamine (MTDATA), but is not limited thereto.

The first unit UN1 may include the first lower emission layer 222-1, the second lower emission layer 222-2, the third lower emission layer 222-3, and the lower active layer 222-4 and may further include a first common layer 221 and a second common layer 223. The first common layer 221 may include a 1-1 common layer 221a and a 1-2 common layer 221b. In detail, the 1-1 common layer 221a and the 1-2 common layer 221b may be arranged between the first pixel electrode 210-1 and the first lower emission layer 222-1, between the second pixel electrode 210-2 and the second lower emission layer 222-2, between the third pixel electrode 210-3 and the third lower emission layer 222-3, and between the fourth pixel electrode 210-4 and the lower active layer 222-4. The second common layer 223 may be arranged between the first lower emission layer 222-1 and the first charge generation layer 224-1, between the second lower emission layer 222-2 and the second charge generation layer 224-2, and between the third lower emission layer 222-3 and the third charge generation layer 224-3. Each of the first common layer 221 and the second common layer 223 may be integrally formed over the first display element DPE1, the second DPE2, and the third display element DPE3.

In other words, the first unit UN1 of the first pixel PX1 may include the 1-1 common layer 221a, the 1-2 common layer 221b, the first lower emission layer 222-1, and the second common layer 223 which are sequentially stacked on the first pixel electrode 210-1. The first unit UN1 of the second pixel PX2 may include the 1-1 common layer 221a, the 1-2 common layer 222b, the second lower emission layer 222-2, and the second common layer 223 which are sequentially stacked on the second pixel electrode 210-2. The first unit UN1 of the third pixel PX3 may include the 1-1 common layer 221a, the 1-2 common layer 221b, the third lower emission layer 222-3, and the second common layer 223 which are sequentially stacked on the third pixel electrode 210-3. The first unit UN1 of the first photo detector LS1 may include the 1-1 common layer 221a, the 1-2 common layer 221b, the lower active layer 222-4, and the second common layer 223 which are sequentially stacked on the fourth pixel electrode 210-4. Each of the 1-1 common layer 221a, the 1-2 common layer 221b, and the second common layer 223 may be a common layer that is continuously formed over the first pixel PX1, the second pixel PX2, the third pixel PX3, and the first photo detector LS1.

The first common layer 221 may be a layer or layers. For example, when the first common layer 221 includes a low-molecular-weight material, the 1-1 common layer 221a may be a Hole Injection Layer (HIL), and the 1-2 common layer 221b may be a Hole Transport Layer (HTL). When the first common layer 221 includes a high-molecular-weight material, the first common layer 221 may be an HTL having a single-layer structure and include poly-(3,4)-ethylene-dihydroxy thiophene (PEDOT) or polyaniline (PANI). The second common layer 223 may not always be included and optionally formed. The second common layer 223 may be a layer or layers. The second common layer 223 may include an Electron Transport Layer (ETL) and/or an Electron Injection Layer (EIL).

In an embodiment, the second unit UN2 may include the first upper emission layer 226-1, the second upper emission layer 226-2, the third upper emission layer 226-3, and the upper active layer 226-4 and further include a third common layer 225, a buffer layer 227, and a fourth common layer 228. In detail, the third common layer 225 may be arranged between the first charge generation layer 224-1 and the first upper emission layer 226-1, between the second charge generation layer 224-2 and the second upper emission layer 226-2, between the third charge generation layer 224-3 and the third upper emission layer 226-3, and between the second common layer 223 and the upper active layer 226-4. The buffer layer 227 and the fourth common layer 228 may be arranged between the first upper emission layer 226-1 and the opposite electrode 230, between the second upper emission layer 226-2 and the opposite electrode 230, between the third upper emission layer 226-3 and the opposite electrode 230, and between the upper active layer 226-4 and the opposite electrode 230. Each of the third common layer 225, the buffer layer 227, and the fourth common layer 228 may be integrally formed over the first display element DPE1, the second display element DPE2, the third display element DPE3, and the first light-receiving element PD1.

In other words, the second unit UN2 of the first pixel PX1 may include the third common layer 225, the first upper emission layer 226-1, the buffer layer 227, and the fourth common layer 228 which are sequentially stacked on the first charge generation layer 224-1. The second unit UN2 of the second pixel PX2 may include the third common layer 225, the second upper emission layer 226-2, the buffer layer 227, and the fourth common layer 228 which are sequentially stacked on the second charge generation layer 224-2. The second unit UN2 of the third pixel PX3 may include the third common layer 225, the third upper emission layer 226-3, the buffer layer 227, and the fourth common layer 228 which are sequentially stacked on the third charge generation layer 224-3. The second unit UN2 of the first photo detector LS1 may include the third common layer 225, the upper active layer 226-4, the buffer layer 227, and the fourth common layer 228 which are sequentially stacked. Each of the third common layer 225, the buffer layer 227, and the fourth common layer 228 may be a common layer that is continuously formed over the first pixel PX1, the second pixel PX2, the third pixel PX3, and the first photo detector LS1.

The third common layer 225 may be a layer or layers. When the third common layer 225 includes a high-molecular-weight material, the third common layer 225 may be an HTL having a single-layer structure and include PEDOT or PANI. When the third common layer 225 includes a low-molecular-weight material, the third common layer 225 may include an HIL and an HTL. Each of the buffer layer 227 and the fourth common layer 228 may not always be included and optionally formed. The buffer layer 227 may include an inorganic material, such as silicon oxide, silicon nitride, and/or silicon oxynitride. The fourth common layer 228 may be a layer or layers. The fourth common layer 228 may include an ETL and/or an EIL.

Thicknesses of the first lower emission layer 222-1 and the first upper emission layer 226-1, thicknesses of the second lower emission layer 222-2 and the second upper emission layer 226-2, and thicknesses of the third lower emission layer 222-3 and the third upper emission layer 226-3 may be determined according to a resonance distance. Each emission layer may further include an auxiliary layer (not shown). In an embodiment, the auxiliary layers (not shown) may be respectively arranged between the first upper emission layer 226-1 and the third common layer 225, between the second upper emission layer 226-2 and the third common layer 225, and between the third upper emission layer 226-3 and the third common layer 225. The auxiliary layer (not shown) may be added to match a resonance distance and include a resonance auxiliary material. For example, the auxiliary layer may include the same material as the HTL. The auxiliary layer may be included in at least one of the first display element DPE1, the second display element DPE2, and the third display element DPE3 to match the resonance distance of each of the first pixel PX1, the second pixel PX2, and the third pixel PX3. For example, the first display element DPE1 may include an auxiliary layer, and the auxiliary layer may be disposed under the first upper emission layer 226-1. Alternatively, the second display element DPE2 may include an auxiliary layer, and the auxiliary layer may be disposed under the second upper emission layer 226-2. The third display element DPE3 may include an auxiliary layer, and the auxiliary layer may be disposed under the third upper emission layer 226-3.

The first display element DPE1, the second display element DPE2, the third display element DPE3, and the first light-receiving element PD1 may further include a capping layer (not shown) arranged on an outer side of the opposite electrode 230. The capping layer may be configured to improve the emission efficiency according to the principle of constructive interference. Thus, the light extraction efficiency of the first display element DPE1, the second display element DPE2, and the third display element DPE3 may increase, and the emission efficiency thereof may increase. Furthermore, the light detection efficiency of the first light-receiving element PD1 increases, and thus, the sensing sensitivity thereof may be improved.

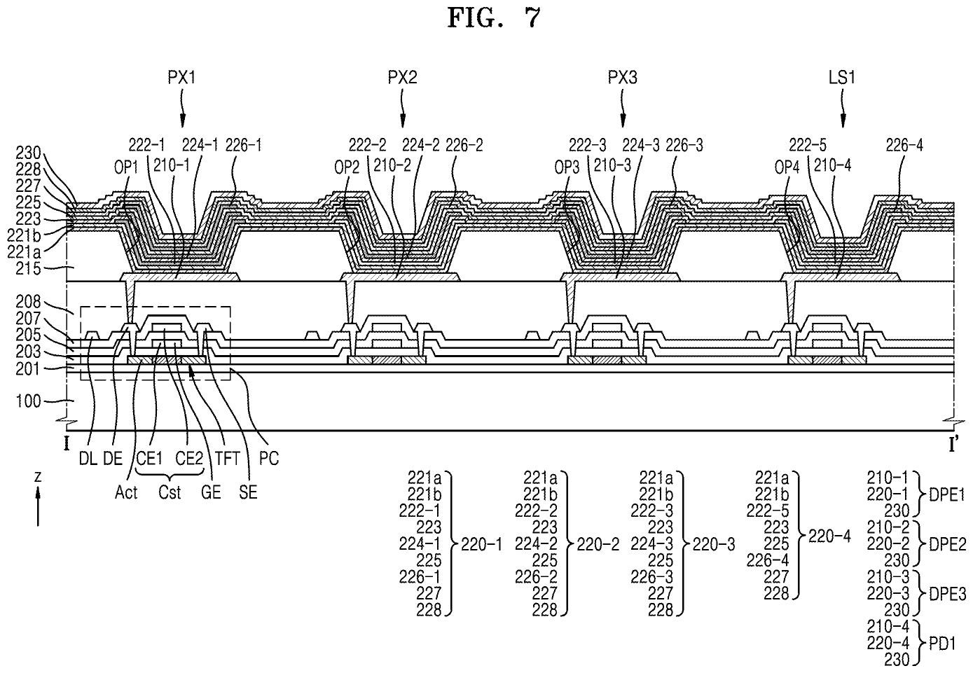

FIG. 7 is a schematic cross-sectional view of a display apparatus according to another embodiment. Referring to FIG. 7, except for features regarding a lower active layer 222-5, other features are the same as those described with reference to FIGS. 4 to 6. The descriptions regarding the same elements shown in FIG. 7 are replaced with the descriptions provided with reference to FIGS. 4 to 6, and differences therebetween are mainly described hereinafter.

Referring to FIG. 7, the fourth intermediate layer 220-4 included in the first light-receiving element PD1 may include active layers. In detail, the fourth intermediate layer 220-4 may include the lower active layer 222-5 and the upper active layer 226-4. The lower active layer 222-5 may be disposed over the fourth pixel electrode 210-4, and the upper active layer 226-4 may be disposed over the lower active layer 222-5 to overlap the same. The lower active layer 222-5 may be arranged on substantially the same layer as the first lower emission layer 222-1, the second lower emission layer 222-2, and the third lower emission layer 222-3 and thus form the first unit UN1. The upper active layer 226-4 may be arranged on substantially the same layer as the first upper emission layer 226-1, the second upper emission layer 226-2, and the third upper emission layer 226-3 and thus form the second unit UN2.

The first light-receiving element PD1 may detect the light emitted from the first display element DPE1, the second display element DPE2, and the third display element DPE3 and reflected from the object. To realize such light detection, each of the lower active layer 222-5 and the upper active layer 226-4 may detect light in a visible band which is emitted from the first to third display elements DPE1, DPE2, and DPE3 and reflected from the object. In detail, each of the lower active layer 222-5 and the upper active layer 226-4 may absorb the light in the visible band, specifically, visible rays included in the green light and having a wavelength greater than or equal to about 495 nm and less than or equal to about 570 nm. Because the lower active layer 222-5 and the upper active layer 226-4 include different materials, wavelength ranges of detectable light in the lower active layer 222-5 and the upper active layer 226-4 may be different from each other.

That is, as the first light-receiving element PD1 included in the first photo detector LS1 includes the lower active layer 222-5, which absorbs the light in the visible band, and the upper active layer 226-4, which also absorbs the light in the visible band but absorbs light in a different wavelength range from that absorbed by the lower active layer 222-5 and is disposed on the lower active layer 222-5, the first light-receiving element PD1 may have a dual detector structure. In particular, when the lower active layer 222-5 is formed to absorb the light in a higher wavelength band than that absorbed by the upper active layer 226-4, the first photo detector LS1 may primarily absorb a short wavelength in the upper active layer 226-4, which is arranged on a relatively upper portion of the display apparatus, and then a long wavelength in the lower active layer 222-5 which is arranged on a relatively lower portion of the display apparatus. In particular, the lower active layer 222-5 and the upper active layer 226-4 are formed to overlap each other, a planar area may be efficiently utilized in the display apparatus, and the resolution of the display apparatus may increase. In addition, the range of the wavelength detectable by the first photo detector LS1 increases compared to when there is only one active layer, the improvements in the sensing sensibility and the sensing reliability of the first photo detector LS1 may be achieved at the same time. Also, when the lower active layer 222-5 and the upper active layer 226-4 include different materials, potential differences of respective layers are different, and thus, a sensor may work smoothly.

A thickness of each of the lower active layer 222-5 and the upper active layer 226-4 may be arranged from about 200 Å to about 2000 Å. The thickness of each of the lower active layer 222-5 and the upper active layer 226-4 may preferably be arranged from about 300 Å to about 700 Å.

Also, each of the lower active layer 222-5 and the upper active layer 226-4 may include a p-type organic semiconductor and an n-type organic semiconductor. Each of the lower active layer 222-5 and the upper active layer 226-4 may have a dual-layer structure that includes a p-type semiconductor layer including the p-type organic semiconductor and an n-type semiconductor layer including the n-type organic semiconductor. Alternatively, each of the lower active layer 222-5 and the upper active layer 226-4 may be a mixed layer in which the p-type organic semiconductor and the n-type organic semiconductor are mixed. The p-type organic semiconductor and the n-type organic semiconductor, which may be included in the lower active layer 222-5 and the upper active layer 226-4, are the same as those described with reference to FIGS. 5 and 6.

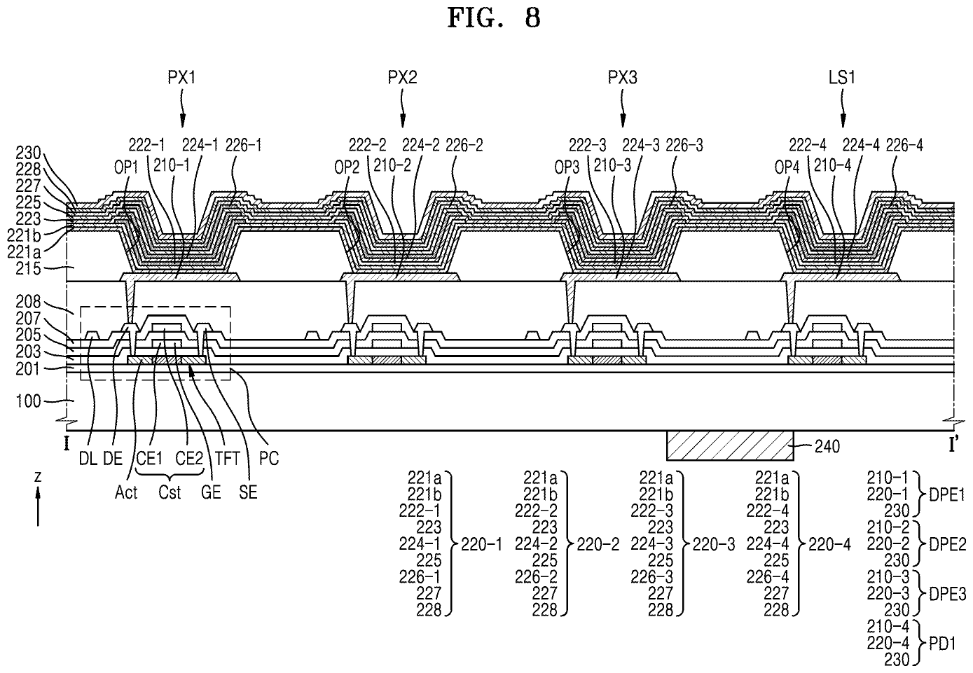

FIG. 8 is a schematic cross-sectional view of a display apparatus according to another embodiment. Referring to FIG. 8, except for features regarding a fourth charge generation layer 224-4, other features are the same as those described with reference to FIGS. 4, 5, and 6. The descriptions regarding the same elements shown in FIG. 8 are replaced with the descriptions provided with reference to FIGS. 4, 5, and 6, and differences therebetween are mainly described hereinafter.

Referring to FIG. 8, the charge generation layers 224-1, 224-2, 224-3, and 224-4 may be arranged between the first lower emission layer 222-1 and the first upper emission layer 226-1, between the second lower emission layer 222-2 and the second upper emission layer 226-2, between the third lower emission layer 222-3 and the third upper emission layer 226-3, and between the lower active layer 222-4 and the upper active layer 226-4, respectively. As shown in FIG. 8, the charge generation layers 224-1, 224-2, and 224-3 may include the first charge generation layer 224-1 arranged between the first lower emission layer 222-1 and the first upper emission layer 226-1, the second charge generation layer 224-2 arranged between the second lower emission layer 222-2 and the second upper emission layer 226-2, the third charge generation layer 224-3 arranged between the third lower emission layer 222-3 and the third upper emission layer 226-3, and the fourth charge generation layer 224-4 arranged between the lower active layer 222-4 and the upper active layer 226-4. That is, as shown in FIG. 8, in the display apparatus according to another embodiment, the fourth charge generation layer 224-4 may also be arranged in the first sensing area (SA1, see FIG. 4).

The first charge generation layer 224-1, the second charge generation layer 224-2, the third charge generation layer 224-3, and the fourth charge generation layer 224-4 may overlap the first pixel electrode 210-1, the second pixel electrode 210-2, the third pixel electrode 210-3, and the fourth pixel electrode 210-4, respectively. The first charge generation layer 224-1, the second charge generation layer 224-2, the third charge generation layer 224-3, and the fourth charge generation layer 224-4 may be spaced apart from each other. That is, the first charge generation layer 224-1, the second charge generation layer 224-2, the third charge generation layer 224-3, and the fourth charge generation layer 224-4 may be patterned using a FMM.

As shown in FIG. 8, when the first charge generation layer 224-1, the second charge generation layer 224-2, the third charge generation layer 224-3, and the fourth charge generation layer 224-4 are spaced apart from each other, the occurrence of a leakage current in a lateral direction may be restricted, compared to when a charge generation layer 224 is commonly formed on the entire substrate 100. In addition, the first charge generation layer 224-1, the second charge generation layer 224-2, the third charge generation layer 224-3, and the fourth charge generation layer 224-4, which are patterned, may prevent a mixture of colors because of a leakage current, wherein such mixture may be generated by a charge generation layer.

Moreover, compared to when the charge generation layer is arranged only on the first display element DPE1, the second display element DPE2, and the third display element DPE3, a step difference may be compensated for at the same time when a charge generation layer is also arranged on the first light-receiving element PD1. In detail, when a charge generation layer is not arranged on the first light-receiving element PD1, locations of the third common layer 225, the upper active layer 226-4, the buffer layer 227, and the fourth common layer 228, which are arranged on the charge generation layer, may be different on the first to third display elements DPE1 to DPE3 and the first light-receiving element PD1. Accordingly, step differences may be generated in the third common layer 225, the buffer layer 227, and the fourth common layer 228 which are formed entirely over the first pixel PX1, the second pixel PX2, the third pixel PX3, and the first photo detector LS1. However, in the display apparatus of FIG. 8, as the fourth charge generation layer 224-4 is arranged between the lower active layer 222-4 and the upper active layer 226-4, the step differences may be compensated for, and thus, a step coverage, etc. in the third common layer 225, the buffer layer 227, and the fourth common layer 228, which are formed over the entirety of the substrate 100, may be overcome.

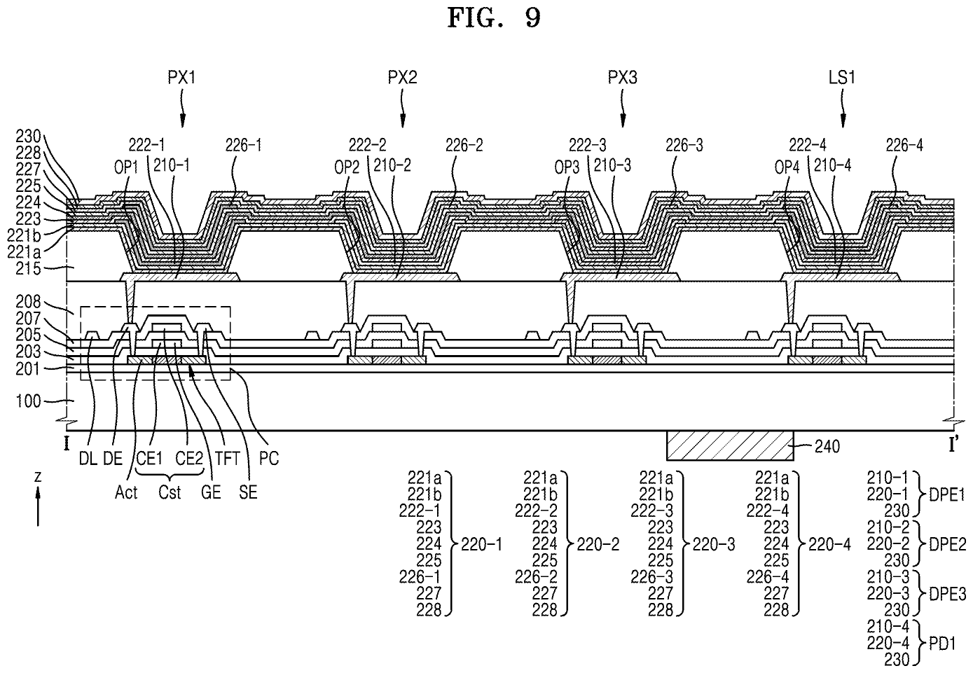

FIG. 9 is a schematic cross-sectional view of a display apparatus according to another embodiment. Referring to FIG. 9, except for features regarding the charge generation layer 224, other features are the same as those described with reference to FIGS. 4, 5, and 6. The descriptions regarding the same elements shown in FIG. 9 are replaced with the descriptions provided with reference to FIGS. 4, 5, and 6, and differences therebetween are mainly described hereinafter.

Referring to FIG. 9, the charge generation layer 224 may be arranged between the first lower emission layer 222-1 and the first upper emission layer 226-1, between the second lower emission layer 222-2 and the second upper emission layer 226-2, between the third lower emission layer 222-3 and the third upper emission layer 226-3, and between the lower active layer 222-4 and the upper active layer 226-4, respectively. That is, the charge generation layer 224 may also be arranged in an area where the first photo detector LS1 is arranged.

As shown in FIG. 9, the charge generation layer 224 may be entirely formed over the first pixel PX1, the second pixel PX2, the third pixel PX3, and the first photo detector LS1. That is, the charge generation layer 224, which is arranged between the first lower emission layer 222-1 and the first upper emission layer 226-1, between the second lower emission layer 222-2 and the second upper emission layer 226-2, between the third lower emission layer 222-3 and the third upper emission layer 226-3, and between the lower active layer 222-4 and the upper active layer 226-4, may extend parallel to the substrate 100. The charge generation layer 224 may have the same area as or a greater area than the display area DA to cover the entirety of the display area DA. The charge generation layer 224 may be deposited using an open mask. When the charge generation layer 224 is arranged over the entireties of the first pixel PX1, the second pixel PX2, the third pixel PX3, and the first photo detector LS1 without being patterned, there is no need for an additional mask, and thus, the manufacturing cost and process time may be reduced.

Moreover, compared to when charge generation layer 224 is arranged only on the first display element DPE1, the second display element DPE2, and the third display element DPE3, a step difference may be compensated for as well when a charge generation layer is also arranged in the first light-receiving element PD1. In detail, when the charge generation layer 224 is not arranged on the first light-receiving element PD1, locations of the third common layer 225, the upper active layer 226-4, the buffer layer 227, and the fourth common layer 228, which are arranged on the charge generation layer 224, may be different in the first to third display elements DPE1, DPE2, and DPE3 and the first light-receiving element PD1. Accordingly, step differences may be generated in the third common layer 225, the buffer layer 227, and the fourth common layer 228 which are formed over the entireties of the first pixel PX1, the second pixel PX2, the third pixel PX3, and the first photo detector LS1. However, in the display apparatus of FIG. 9, as the charge generation layer 224 extends and is arranged between the lower active layer 222-4 and the upper active layer 226-4, the step difference may be compensated for, and thus, a step coverage, etc. in the third common layer 225, the buffer layer 227, and the fourth common layer 228, which are formed over the entirety of the substrate 100, may be overcome.

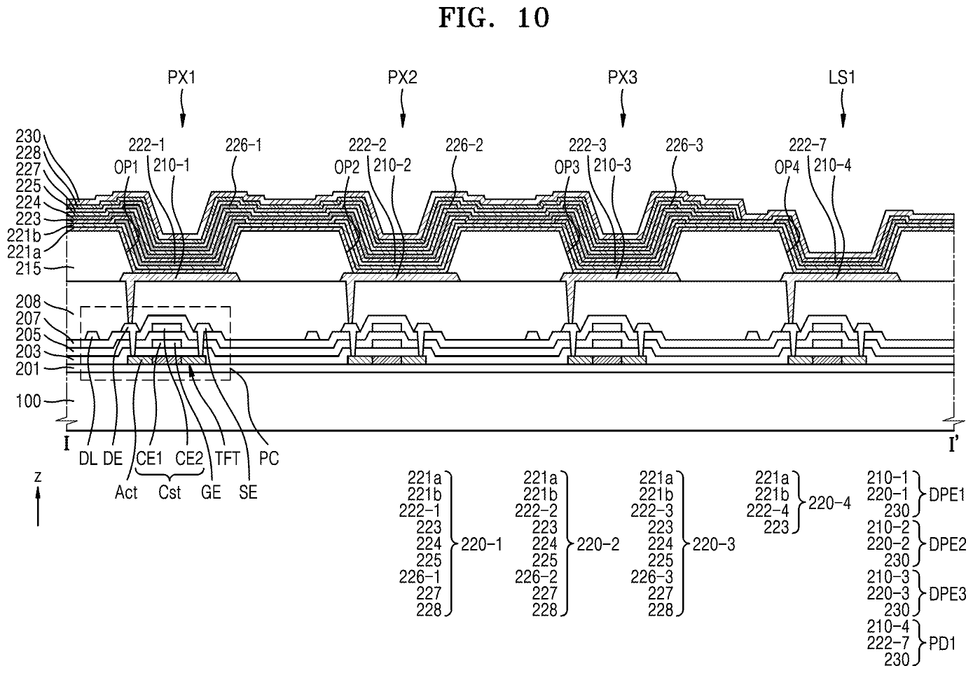

FIG. 10 is a schematic cross-sectional view of a display apparatus according to another embodiment. Referring to FIG. 10, except for features regarding the first light-receiving element PD1, other features are the same as those described with reference to FIGS. 4, 5, and 6. The descriptions regarding the same elements shown in FIG. 10 are replaced with the descriptions provided with reference to FIGS. 4, 5, and 6, and differences therebetween are mainly described hereinafter.

The first light-receiving element PD1 may include the fourth pixel electrode 210-4, the fourth intermediate layer 220-4, and the opposite electrode 230. That is, the fourth intermediate layer 220-4 may be arranged between the fourth pixel electrode 210-4 and the opposite electrode 230.

Each of the first display element DPE1, the second display element DPE2, and the third display element DPE3 has a tandem structure including emission layers, but the first light-receiving element PD1 of the display apparatus of FIG. 10 may have a single detector structure including an active layer. That is, each of the first intermediate layer 220-1, the second intermediate layer 220-2, and the third intermediate layer 220-3, which are respectively included in the first display element DPE1, the second display element DPE2, and the third display element DPE3, may include the emission layers, but the fourth intermediate layer 220-4 included in the first light-receiving element PD1 may include a single active layer.

In an embodiment, the fourth intermediate layer 220-4 may include an active layer 222-7, and the active layer 222-7 may be substantially arranged on the same layer as the first lower emission layer 222-1, the second lower emission layer 222-2, and the third lower emission layer 222-3. In this case, the first lower emission layer 222-1, the second lower emission layer 222-2, the third lower emission layer 222-3, and the active layer 222-7 may be separately patterned. The first lower emission layer 222-1, the second lower emission layer 222-2, the third lower emission layer 222-3, and the active layer 222-7 may form the first unit UN1. That is, the first light-receiving element PD1 may have a structure in which the fourth pixel electrode 210-4, the 1-1 common layer 221a, the 1-2 common layer 221b, the active layer 222-7, the second common layer 223, and the opposite electrode 230 are sequentially stacked. In this case, the third common layer 225, the buffer layer 227, and the fourth common layer 228, which are included in the second unit UN2, and the charge generation layer 224 may be arranged in an area except for the first sensing area (SA1, see FIG. 4).

However, one or more embodiments are not limited thereto, and in another embodiment, the active layer 222-7 may be substantially arranged on the same layer as the first upper emission layer 226-1, the second upper emission layer 226-2, and the third upper emission layer 226-3. In this case, the first upper emission layer 226-1, the second upper emission layer 226-2, the third upper emission layer 226-3, and the active layer 222-7 may be separately patterned. The first upper emission layer 226-1, the second upper emission layer 226-2, the third upper emission layer 226-3, and the active layer 222-7 may form the second unit UN2. That is, the first light-receiving element PD1 may have a structure in which the fourth pixel electrode 210-4, the third common layer 225, the active layer 222-7, the fourth common layer 228, and the opposite electrode 230 are sequentially stacked. In this case, the 1-1 common layer 221a, the 1-2 common layer 221b, and the second common layer 223, which are included in the first unit UN1, and the charge generation layer 224 may be arranged in an area except for the first sensing area (SA1, see FIG. 4).

Accordingly, the first light-receiving element PD1 may detect light emitted from the first display element DPE1, the second display element DPE2, and the third display element DPE3 and reflected from the object. To realize the light detection, the active layer 222-7 may detect light in a visible band which is emitted from the first display element DPE1, the second display element DPE2, and the third display element DPE3 and reflected from the object. In detail, the active layer 222-7 may absorb the light in the visible band, specifically, visible rays included in the green light and having a wavelength greater than or equal to about 495 nm and less than or equal to about 570 nm.

That is, in the display apparatus of FIG. 10, as each of the first to third display elements DPE1, DPE2, and DPE3 may have a stack structure including the emission layers, the color purity and emission efficiency of the display apparatus may be improved. Moreover, a photo detector may be efficiently placed in the display apparatus by using common layers, which are included in the first to third display elements DPE1, DPE2, and DPE3, also in the first light-receiving element PD1.

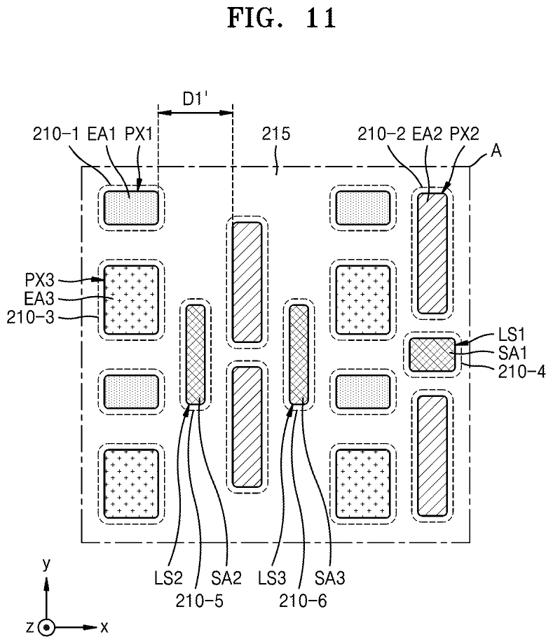

FIG. 11 is a schematic plan view of a portion of a display apparatus according to another embodiment. Referring to FIG. 11, except for features regarding the second pixel PX2 and photo detectors LS1, LS2, and LS3, other features are the same as those described with reference to FIG. 4. The descriptions regarding the same elements shown in FIG. 11 are replaced with the descriptions provided with reference to FIG. 4, and differences therebetween are mainly described hereinafter.

Referring to FIG. 11, the display apparatus may include pixels and photo detectors. The pixels may include the first pixel PX1, the second pixel PX2, and the third pixel PX3, and the photo detectors may include the first photo detector LS1, a second photo detector LS2, and a third photo detector LS3. The first photo detector LS1, the second photo detector LS2, and the third photo detector LS3 may sense an object by using light emitted from the first pixel PX1, the second pixel PX2, and the third pixel PX3 and reflected from the object.

Each pixel may include a display element, and each photo detector may include a light-receiving element. The display element and the light-receiving element may each include a pixel electrode, an opposite electrode, and an intermediate layer arranged therebetween. Accordingly, the first photo detector LS1 may include the fourth pixel electrode 210-4, the second photo detector LS2 may include a fifth pixel electrode 210-5, and the third photo detector LS3 may include a sixth pixel electrode 210-6. The first to sixth pixel electrodes 210-1, 210-2, 210-3, 210-4, 210-5, and 210-6 may be spaced apart from each other above the substrate (100, see FIG. 5). Active layers for detecting light may be located in a fourth opening OP4, a fifth opening OP5, and a sixth opening OP6 of the bank layer 215, respectively. The opposite electrodes may be disposed on the emission layers and the active layers.

The active layer for detecting light may be arranged in the fourth opening OP4, and the first photo detector LS1 may include the first sensing area SA1 defined by the fourth opening OP4. Similarly, the active layer for detecting light may also be arranged in the fifth opening OP5, and the second photo detector LS2 may include a second sensing area SA2 defined by the fifth opening OP5. The active layer for detecting light may also be arranged in the sixth opening OP6, and the third photo detector LS3 may include a third sensing area SA3 defined by the sixth opening OP6.

In a plane, the first pixels PX1 and the third pixels PX3 may be alternately arranged in a first column in a first direction (e.g., a y direction). That is, the first emission areas EA1 and the third emission areas EA3 may be alternately arranged in the first column. As described, the second pixels PX2 may be repeatedly arranged in a second column in the first direction (e.g., the y direction). That is, the second emission areas EA2 may be repeatedly arranged in the second column. The first column and the second column may be arbitrarily determined and alternately arranged in a second direction (e.g., an x direction) perpendicular to the first direction.

As the first pixel PX1, the second pixel PX2, and the third pixel PX3 each have a tandem structure including the emission layers, an increase degree of a duration of the second pixel PX2 emitting blue light may be greater than an increase degree of a duration of the first pixel PX1 emitting red light and an increase degree of a duration of the third pixel PX3 emitting green light. Accordingly, when each pixel includes a plurality of emission layers, an area of an opening of a pixel emitting blue light may be reduced compared to an area of an opening of a pixel including a single emission layer and emitting blue light. That is, when the tandem structure is applied to each pixel, an area of the second emission area EA2 may decrease. When the area of the second emission area EA2 decreases, a first distance D1′ of FIG. 11 from the first pixel PX1 to the second pixel PX2 may be greater than the first distance D1 of FIG. 4 from the first pixel PX1 to the second pixel PX2. That is, sizes of a non-display area between the second pixel PX2 and the first pixel PX1 as shown in FIG. 11 may be larger than that between the second pixel PX2 and the first pixel PX1 as shown in FIG. 4. Further, a non-display area of the second pixel PX2 and the third pixel PX3 as shown in FIG. 11 may be larger than that of the second pixel PX2 and the third pixel PX3 as shown in FIG. 4.

Thus, in the display apparatus shown in FIG. 11, the second photo detector LS2 and the third photo detector LS3 may be additionally arranged. In detail, because the non-display area between the second pixel PX2 and the first pixel PX1 increases, the second photo detector LS2 may be additionally arranged on a side of the second pixel PX2, and the third photo detector LS3 may be additionally arranged on the other side of the second pixel PX2. However, additional photo detectors are not limited thereto, and the photo detectors may be freely arranged in an increased non-pixel area.

As a result, a planar area of a display apparatus according to another embodiment may be effectively utilized while the display quality thereof is maintained. In addition, because the second photo detector LS2 and the third photo detector LS3 are added, the sensing sensitivity and the sensing reliability may also be improved.

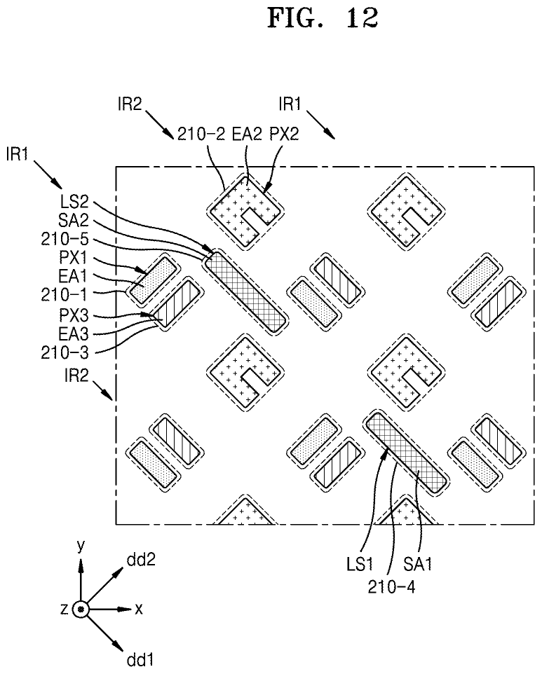

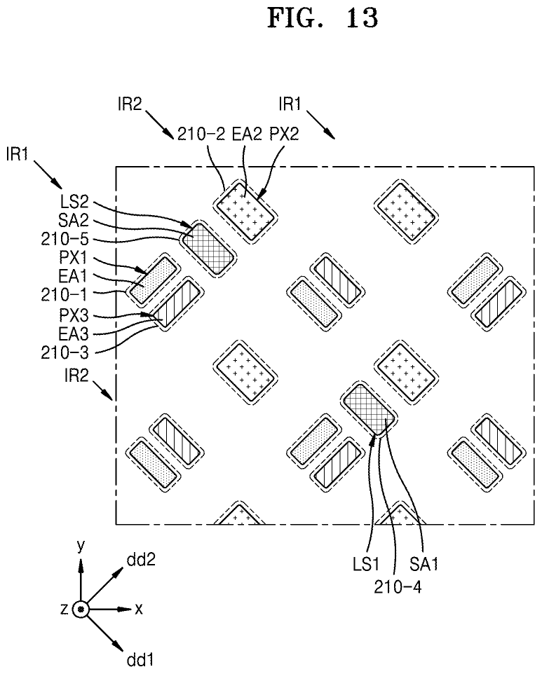

FIG. 12 is a schematic plan view of a portion of a display apparatus according to another embodiment, and FIG. 13 is a schematic plan view of a portion of a display apparatus according to another embodiment.

Referring to FIGS. 12 and 13, the second pixels PX2 may be arranged on lattice points located at certain intervals in a first direction (e.g., an x direction) and a second direction (e.g., a y direction) perpendicular to the first direction. The first pixels PX1 and the third pixels PX3 may be arranged between the second pixels PX2 arranged in the aforementioned manner. In detail, a pair of first pixel PX1 and third pixel PX3 may be arranged between two adjacent second pixels PX2.

For example, in oblique columns IR1 and IR2 extending in a third direction dd1 forming an angle of approximately 45 degrees with the first direction (e.g., the x direction), the pair of first pixel PX1 and third pixel PX3 may be arranged between the second pixels PX2. The pair of first pixel PX1 and third pixel PX3 may extend in the third direction dd1 or a fourth direction dd2 substantially perpendicular to the third direction dd1. In detail, the first oblique columns IR1 and the second oblique columns IR2 may be alternately arranged. In the first oblique columns IR1, the pair of first pixel PX1 and third pixel PX3 extending in the third direction dd1 may be arranged. In the second oblique columns IR2, the pair of first pixel PX1 and third pixel PX3 extending in the fourth direction dd2 may be arranged.

Referring to FIG. 12, the second pixel PX2 may have a ‘U’ shape. FIG. 12 is a plan view on the bank layer 215 for convenience, but the second pixel PX2 may include at least one organic layer. When such an organic layer is formed, gases may be generated in the organic layer, and the generated gases need to be emitted to outside of the organic layer. When the area of the second pixel PX2 is excessively great, the amount of gases generated inside the organic layer is great while the organic layer is formed, and thus, vent holes may be formed to easily emit the gases. Therefore, the second pixel PX2 may have the ‘U’ shape.

As shown in FIG. 12, the first photo detector LS1 and the second photo detector LS2 may be arranged between the second pixel PX2 and the first pixel PX1 or between the second pixel PX2 and the third pixel PX3. That is, the first sensing area SA1 and the second sensing area SA2 may be located in the non-pixel area between the second emission area EA2 and the first emission area EA1 or the non-pixel area between the second emission area EA2 and the third emission area EA3.

As described above, the first pixel PX1, the second pixel PX2, and the third pixel PX3 each have the tandem structure including the emission layers, the increase degree of the duration of the second pixel PX2 emitting blue light may be greater than the increase degree of the duration of the first pixel PX1 emitting red light and the increase degree of the duration of the third pixel PX3 emitting green light. Accordingly, when each pixel includes a plurality of emission layers, an area of an opening of a pixel emitting blue light may be reduced compared to an area of an opening of a pixel including a single emission layer and emitting blue light. That is, when the tandem structure is applied to each pixel, the area of the second emission area EA2 may decrease.

When the area of the second emission area EA2 decreases, the amount of gases generated in the organic layer decreases, and thus, vent holes may not be formed. Therefore, as shown in FIG. 13, the second pixel PX2 may not have the ‘U’ shape. The second pixel PX2 of FIG. 13 may have a square shape. However, the shape of the second pixel PX2 is not limited thereto.

Referring to FIG. 13, the area of the second emission area EA2 of the second pixel PX2 may be less than that of the third emission area EA3 of the third pixel PX3. Accordingly, a distance between the first pixel PX1 and the second pixel PX2 may be greater than a distance between the first pixel PX1 and the third pixel PX3. Also, a distance of FIG. 13 from the first pixel PX1 to the second pixel PX2 may be greater than a distance of FIG. 12 from the first pixel PX1 to the second pixel PX2. That is, the sizes of the non-pixel area between the second pixel PX2 and the first pixel PX1 and the non-pixel area between the second pixel PX2 and the third pixel PX3 may increase.

Thus, in the display apparatus shown in FIG. 13, the first photo detector LS1 and the second photo detector LS2 may be arranged in the increased non-pixel areas. When the first and second photo detectors LS1 and LS2 are arranged in the non-pixel areas, margins may be secured enough, and thus, the display area DA may be utilized to the maximum extent.

As a result, in the display apparatuses of FIGS. 12 and 13, the planar areas may be efficiently used while the display quality thereof is maintained. As the first and second photo detectors LS1 and LS2 may be added, the sensing sensitivity and the sensing reliability thereof may also be improved.

According to the one or more embodiments, the display quality of a display apparatus and the sensing sensitivity of a photo detector may be improved. The above effect is merely an example, and the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate including a first emission area, a second emission area, a third emission area, and a sensing area;
a first organic light-emitting diode disposed on the substrate, corresponding to the first emission area, and emitting a first light;
a second organic light-emitting diode disposed on the substrate, corresponding to the second emission area, and emitting a second light;
a third organic light-emitting diode disposed on the substrate, overlapping the third emission area, and emitting a third light; and
a photo detector disposed on the substrate and overlapping the sensing area,
wherein the first organic light-emitting diode includes a first pixel electrode, a first lower emission layer disposed on the first pixel electrode, a first upper emission layer disposed on the first lower emission layer, and an opposite electrode disposed on the first upper emission layer,
the second organic light-emitting diode includes a second pixel electrode, a second lower emission layer disposed on the second pixel electrode, a second upper emission layer disposed on the second lower emission layer, and the opposite electrode disposed on the second upper emission layer,
the third organic light-emitting diode includes a third pixel electrode, a third lower emission layer disposed on the third pixel electrode, a third upper emission layer disposed on the third lower emission layer, and the opposite electrode disposed on the third upper emission layer, and
the photo detector includes a fourth pixel electrode, an active layer disposed on the fourth pixel electrode, and the opposite electrode disposed on the active layer.

2. The display apparatus of claim 1, further comprising a charge generation layer disposed on the first lower emission layer, the second lower emission layer, and the third lower emission layer and simultaneously disposed under the first upper emission layer, the second upper emission layer, and the third upper emission layer.

3. The display apparatus of claim 2, wherein the active layer includes a lower active layer and an upper active layer disposed on the lower active layer,
the lower active layer is arranged on a same layer as the first lower emission layer, the second lower emission layer, and the third lower emission layer, and
the upper active layer is arranged on a same layer as the first upper emission layer, the second upper emission layer, and the third upper emission layer.

4. The display apparatus of claim 3, wherein wavelength ranges of detectable light in the lower active layer and the upper active layer are different from each other.

5. The display apparatus of claim 4, further comprising a near-infrared ray emitting portion configured to emit near-infrared rays having a wavelength greater than or equal to about 750 nm and less than or equal to about 1000 nm.

6. The display apparatus of claim 5, wherein the near-infrared ray emitting portion is arranged on a lower surface of the substrate.

7. The display apparatus of claim 5, wherein the lower active layer absorbs near-infrared rays having a wavelength greater than or equal to about 750 nm and less than or equal to about 1000 nm, and
the upper active layer absorbs visible rays having a wavelength greater than or equal to about 495 nm and less than or equal to about 570 nm.

8. The display apparatus of claim 4, wherein the lower active layer and the upper active layer absorb visible rays having a wavelength greater than or equal to about 495 nm and less than or equal to about 570 nm.

9. The display apparatus of claim 3, wherein the charge generation layer is arranged between the lower active layer and the upper active layer to overlap the sensing area.

10. The display apparatus of claim 9, wherein the first pixel electrode, the second pixel electrode, the third pixel electrode, and the fourth pixel electrode are spaced apart from each other,
the charge generation layer includes a first charge generation layer overlapping the first pixel electrode, a second charge generation layer overlapping the second pixel electrode, a third charge generation layer overlapping the third pixel electrode, and a fourth charge generation layer overlapping the fourth pixel electrode, and
the first charge generation layer, the second charge generation layer, the third charge generation layer, and the fourth charge generation layer are spaced apart from each other.

11. The display apparatus of claim 9, wherein the charge generation layer extends and is disposed over an entirety of the substrate to overlap each of the first pixel electrode, the second pixel electrode, the third pixel electrode, and the fourth pixel electrode.

12. The display apparatus of claim 3, further comprising:
a first common layer disposed on the first pixel electrode, the second pixel electrode, the third pixel electrode, and the fourth pixel electrode and under the first lower emission layer, the second lower emission layer, and the third lower emission layer;
a second common layer disposed on the first lower emission layer, the second lower emission layer, and the third lower emission layer and under the charge generation layer;
a third common layer disposed on the charge generation layer and under the first upper emission layer, the second upper emission layer, and the third upper emission layer; and
a fourth common layer disposed on the first upper emission layer, the second upper emission layer, and the third upper emission layer, and under the opposite electrode.

13. The display apparatus of claim 12, wherein, in the sensing area, the active layer is disposed on the first common layer, the second common layer is disposed on the active layer, and the opposite electrode is disposed on the second common layer, and
the third common layer and the fourth common layer are arranged in an area except the sensing area.

14. The display apparatus of claim 12, wherein, in the sensing area, the third common layer is disposed on the substrate, the active layer is disposed on the third common layer, the fourth common layer is disposed on the active layer, and the opposite electrode is disposed on the fourth common layer, and
the first common layer and the second common layer are arranged in an area except the sensing area.

15. The display apparatus of claim 12, wherein, in the sensing area, the lower active layer is disposed on the first common layer, the second common layer is disposed on the lower active layer, the charge generation layer is disposed on the second common layer, the third common layer is disposed on the charge generation layer, the upper active layer is disposed on the third common layer, the fourth common layer is disposed on the upper active layer, and the opposite electrode is disposed on the fourth common layer.

16. The display apparatus of claim 1, wherein, when viewed in a direction perpendicular to the substrate, the first emission area and the third emission area are alternately arranged in a first column,
the second emission area is repeatedly arranged in a second column parallel to the first column,
the first column and the second column are alternately arranged, and
the sensing area is arranged between the second emission areas that are adjacent to each other.

17. The display apparatus of claim 16, wherein, when viewed in a direction perpendicular to the substrate, a distance between the first emission area and the third emission area is narrower than a distance between the second emission area and the first emission area and a distance between the second emission area and the third emission area, and
the sensing area is located in an area between the first emission area and the second emission area or between the third emission area and the second emission area.

18. The display apparatus of claim 1, wherein, when viewed in a direction perpendicular to the substrate, the first emission area and the third emission area are arranged side by side to form a first configuration,
the second emission area is located between adjacent first configurations,
a distance between the first emission area and the third emission area is narrower than a distance between the second emission area and the first emission area and a distance between the second emission area and the third emission area, and
the sensing area is located between the first emission area and the second emission area or between the third emission area and the second emission area.

19. The display apparatus of claim 2, wherein the charge generation layer includes an n-type charge generation layer and a p-type charge generation layer disposed on the n-type charge generation layer.

20. The display apparatus of claim 12, further comprising an auxiliary layer arranged between the first upper emission layer and the third common layer, between the second upper emission layer and the third common layer, or between the third upper emission layer and the third common layer,
wherein each of the first upper emission layer, the second upper emission layer, and the third upper emission layer contacts the auxiliary layer.

21. The display apparatus of claim 3, wherein a thickness of each of the lower active layer and the upper active layer is between about 300 Å and about 700 Å.

22. The display apparatus of claim 1, wherein the active layer has a double-layer structure that comprises a p-type semiconductor layer including a p-type organic semiconductor and an n-type semiconductor layer including an n-type organic semiconductor.

23. The display apparatus of claim 1, wherein the active layer includes a mixed layer in which a p-type organic semiconductor is mixed with an n-type organic semiconductor.
